(19) United States
(12) Patent Application Publication
(10) Pub. No.: US 2024/0357815 A1
(43) Pub. Date: Oct. 24, 2024

(54) METHODS TO INCREASE CELL DENSITY USING A LATERAL ETCH

(71) Applicant: Micron Technology, Inc., Boise, ID (US)

(72) Inventors: Paolo Fantini, Vimercate (MB) (IT); Lorenzo Fratin, Buccinasco (MI) (IT); Paolo Tessariol, Arcore (MB) (IT); Enrico Varesi, Milano (MI) (IT); Emilio Camerlenghi, Bergamo (BG) (IT); Stephen W. Russell, Boise, ID (US); Yoshiaki Fukuzumi, Yokohama (JP)

(21) Appl. No.: 18/637,127

(22) Filed: Apr. 16, 2024

Related U.S. Application Data
(60) Provisional application No. 63/461,452, filed on Apr. 24, 2023.

(51) Int. Cl. H10B 43/27

(52) U.S. Cl. CPC H10B 43/27

(57) ABSTRACT

Methods, systems, and devices for methods to increase cell density using a lateral etch are described. A process to manufacture a memory array may include a lateral wet etch to split a pillar into two stacks of memory cells. In some cases, the manufacturing process may include forming a trench in a vertical stack of layers and forming a memory cell pillar which includes an oxide material, a semiconductor channel material, and an insulating material in the trench. Sidewalls of the pillar may be laterally etched to remove portions of the oxide material and the semiconductor material, which may form two stacks of memory cells, each stack in contact with opposing sidewalls of the trench. In some examples, the manufacturing process may include forming one or more supportive piers within the trench, and the pillar of memory cell material may be formed between pairs of piers.

### CROSS REFERENCE

The present application for patent claims priority to U.S. Patent Application No. 63/461,452 by Fantini et al., entitled “METHODS TO INCREASE CELL DENSITY USING A LATERAL ETCH,” filed Apr. 24, 2023, which is assigned to the assignee hereof, and which is expressly incorporated by reference in its entirety herein.

### TECHNICAL FIELD

The following relates to one or more systems for memory, including methods to increase cell density using a lateral etch.

### BACKGROUND

Memory devices are widely used to store information in various electronic devices such as computers, user devices, wireless communication devices, cameras, digital displays, and the like. Information is stored by programming memory cells within a memory device to various states. For example, binary memory cells may be programmed to one of two supported states, often corresponding to a logic 1 or a logic 0. In some examples, a single memory cell may support more than two possible states, any one of which may be stored by the memory cell. To access information stored by a memory device, a component may read (e.g., sense, detect, retrieve, identify, determine, evaluate) the state of one or more memory cells within the memory device. To store information, a component may write (e.g., program, set, assign) one or more memory cells within the memory device to corresponding states.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), 3-dimensional cross-point memory (3D cross point), not-or (NOR) and not-and (NAND) memory devices, and others. Memory devices may be described in terms of volatile configurations or non-volatile configurations. Volatile memory cells (e.g., DRAM) may lose their programmed states over time unless they are periodically refreshed by an external power source. Non-volatile memory cells (e.g., NAND) may maintain their programmed states for extended periods of time even in the absence of an external power source.

### BRIEF DESCRIPTION OF THE DRAWINGS

FIG. 1 illustrates an example of a system that supports methods to increase cell density using a lateral etch in accordance with examples as disclosed herein.

FIG. 2 illustrates an example of a memory architecture that supports methods to increase cell density using a lateral etch in accordance with examples as disclosed herein.

FIGS. 3A through 3C illustrate examples of memory arrays that support methods to increase cell density using a lateral etch in accordance with examples as disclosed herein.

FIGS. 4A through 4C illustrate examples of memory arrays that support methods to increase cell density using a lateral etch in accordance with examples as disclosed herein.

FIGS. 5A through 5C illustrate examples of memory arrays that support methods to increase cell density using a lateral etch in accordance with examples as disclosed herein.

FIGS. 6A and 6B illustrate examples of memory arrays that support methods to increase cell density using a lateral etch in accordance with examples as disclosed herein.

FIGS. 7A through 7E illustrate examples of memory arrays that support methods to increase cell density using a lateral etch in accordance with examples as disclosed herein.

FIGS. 8A through 8E illustrate examples of memory arrays that support methods to increase cell density using a lateral etch in accordance with examples as disclosed herein.

FIGS. 9A through 9C illustrate examples of memory arrays that support methods to increase cell density using a lateral etch in accordance with examples as disclosed herein.

FIGS. 10A through 10C illustrate examples of memory arrays that support methods to increase cell density using a lateral etch in accordance with examples as disclosed herein.

FIGS. 11A through 11C illustrate examples of memory arrays that support methods to increase cell density using a lateral etch in accordance with examples as disclosed herein.

FIG. 12 illustrates an example of a memory array that supports methods to increase cell density using a lateral etch in accordance with examples as disclosed herein.

FIGS. 13 and 14 illustrate flowcharts showing a method or methods that support methods to increase cell density using a lateral etch in accordance with examples as disclosed herein.

### DETAILED DESCRIPTION

In some cases, a memory device (e.g., a NAND device) may include a memory array having a vertical architecture. For example, aspects of the memory array may be formed from an alternating stack of materials. Material may be removed from the stack (e.g., etched from the stack) to form a trench, and one or more memory cells may be formed that include one or more materials deposited in the trench in combination with materials of the alternating stack of materials (e.g., using a replacement process to replace one or more of the alternating stack of materials with a conductor or semiconductor). For example, a quantity of memory cells may be formed vertically in the trench, coupled to access lines formed in the alternating stack of materials.

Because the memory density of the array may increase as the quantity of memory cells arranged in a stack within the trench (e.g., the tier count) increases, and as the area of each memory cell (e.g., the product of the length and width of each memory cell) decreases, techniques to decrease cell areas and increase tier count are desired. Some methods to manufacture such a memory device may include forming gate-all-around (GAA) memory cells, in which a single memory cell is coupled with opposing sidewalls of a trench. However, because GAA memory cells may include a gate which surrounds a central pillar of the memory cell, the gate may include regions of material which do not actively support storing charge, and so such GAA memory cells may inefficiently utilize space. Accordingly, methods to decrease cell area may be desired.

As described herein, a manufacturing process to manufacture a memory array may include a lateral etch (e.g., wet etch) to split a pillar into two stacks of memory cells. In some cases, the manufacturing process may include forming a trench in a vertical stack of layers and forming a memory cell pillar which includes an oxide material (e.g., a gate oxide), a semiconductor channel material, and an insulating material in the trench. Sidewalls of the pillar may be laterally etched to remove portions of the oxide material and the semiconductor material, which may form two stacks of memory cells, each stack in contact with one of the opposing sidewalls of the trench. In some examples, the manufacturing process may include forming one or more supportive piers within the trench, and the pillar of memory cell material may be formed between pairs of piers, which may provide mechanical support to the pillar. Such methods may allow for fabrication of memory cells with a reduced cell area (e.g., reduced by half) compared with GAA memory cells, while providing structural support to the memory cells during fabrication.

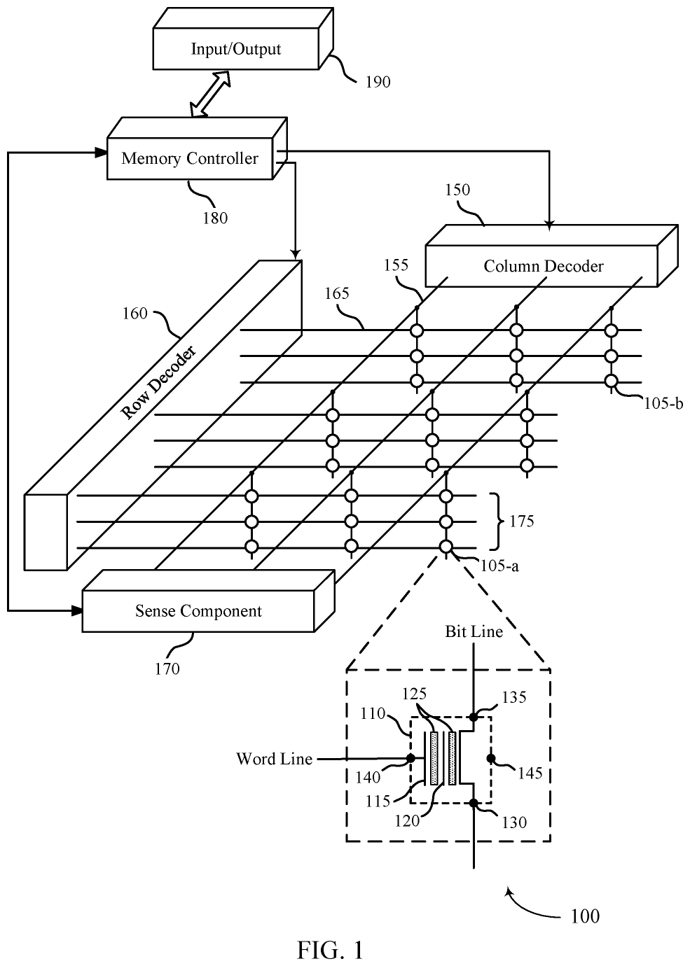

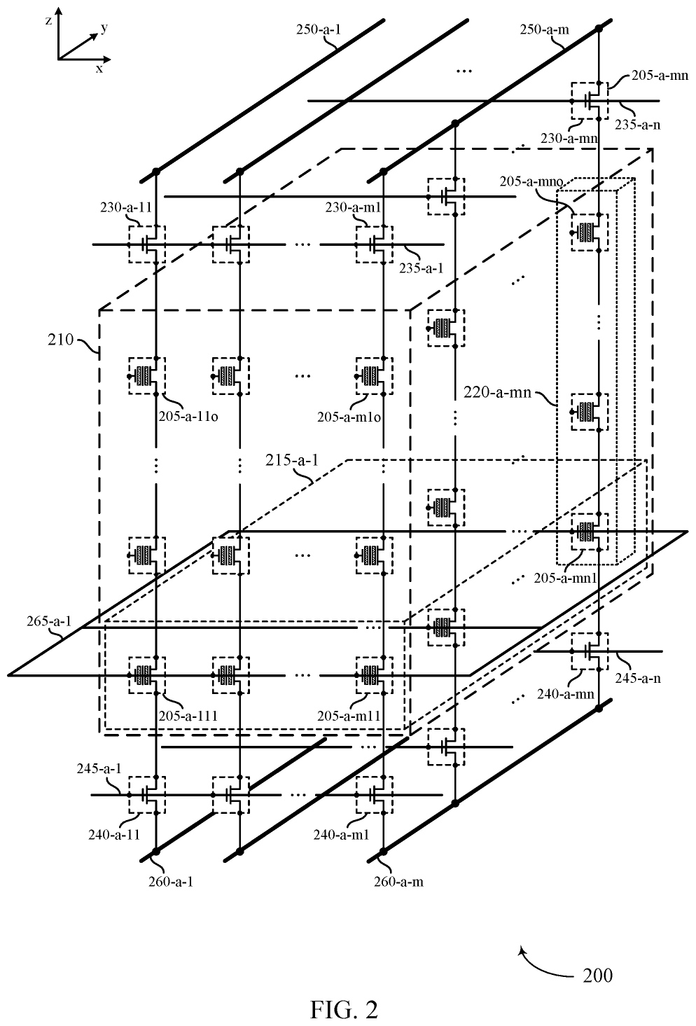

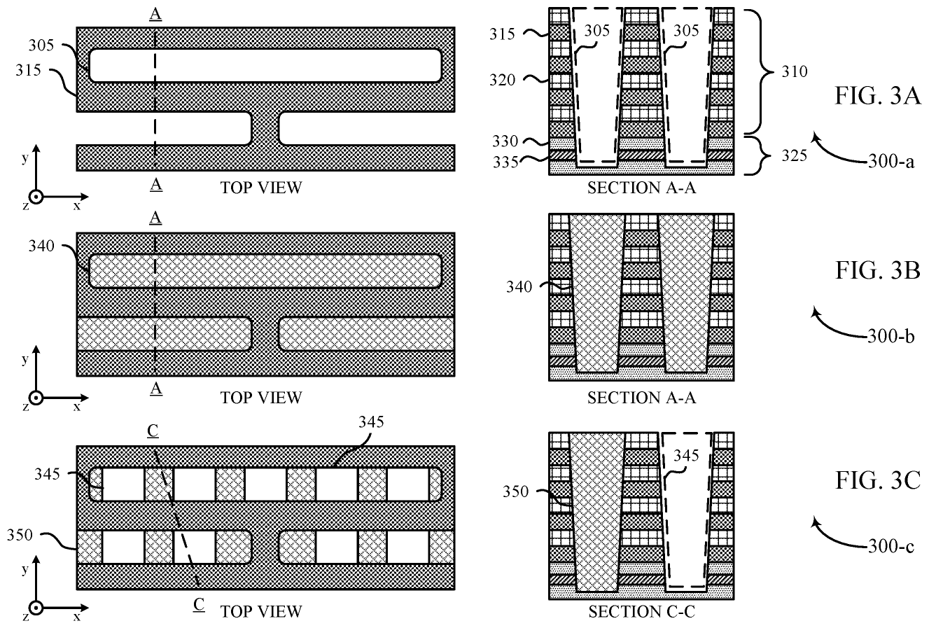

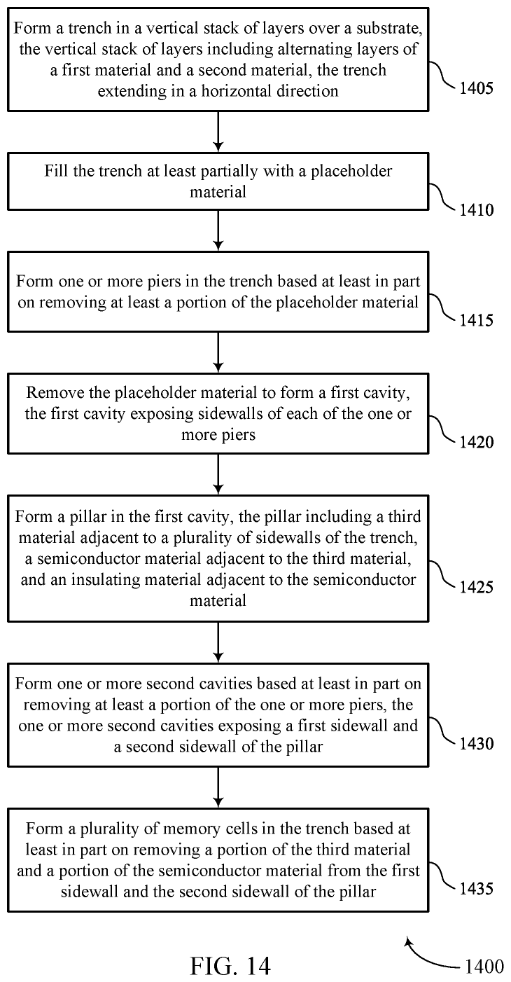

Features of the disclosure are initially described in the context of systems, devices, and circuits with reference to FIGS. 1 and 2. Features of the disclosure are described in the context of memory arrays with reference to FIGS. 3A through 12. These and other features of the disclosure are further illustrated by and described in the context of flowcharts that relate to methods to increase cell density using a lateral etch with reference to FIGS. 13 through 14.

FIG. 1 illustrates an example of a memory device 100 that supports methods to increase cell density using a lateral etch in accordance with examples as disclosed herein. FIG. 1 is an illustrative representation of various components and features of the memory device 100. As such, the components and features of the memory device 100 are shown to illustrate functional interrelationships, and not necessarily physical positions within the memory device 100. Further, although some elements included in FIG. 1 are labeled with a numeric indicator, some other corresponding elements are not labeled, even though they are the same or would be understood to be similar, in an effort to increase visibility and clarity of the depicted features.

The memory device 100 may include one or more memory cells 105, such as memory cell 105-a and memory cell 105-b. In some examples, a memory cell 105 may be a NAND memory cell, such as in the blow-up diagram of memory cell 105-a. Each memory cell 105 may be programmed to store a logic value representing one or more bits of information. In some examples, a single memory cell 105—such as a memory cell 105 configured as a single-level cell (SLC)—may be programmed to one of two supported states and thus may store one bit of information at a time (e.g., a logic 0 or a logic 1). In some other examples, a single memory cell 105—such a memory cell 105 configured as a multi-level cell (MLC), a tri-level cell (TLC), a quad-level cell (QLC), or other type of multiple-level memory cell 105—may be programmed to one state of more than two supported states and thus may store more than one bit of information at a time. In some cases, a multiple-level memory cell 105 (e.g., an MLC memory cell, a TLC memory cell, a QLC memory cell) may be physically different than an SLC cell. For example, a multiple-level memory cell 105 may use a different cell geometry or may be fabricated using different materials. In some examples, a multiple-level memory cell 105 may be physically the same or similar to an SLC cell, and other circuitry in a memory block (e.g., a controller, sense amplifiers, drivers) may be configured to operate (e.g., read and program) the memory cell as an SLC cell, or as an MLC cell, or as a TLC cell, etc.

In some NAND memory arrays, each memory cell 105 may be illustrated as a transistor that includes a charge trapping structure (e.g., a floating gate, a replacement gate, a dielectric material) for storing an amount of charge representative of a logic value. For example, the blow-up in FIG. 1 illustrates a NAND memory cell 105-a that includes a transistor 110 (e.g., a metal-oxide-semiconductor (MOS) transistor) that may be used to store a logic value. The transistor 110 may include a control gate 115 and a charge trapping structure 120 (e.g., a floating gate, a replacement gate), where the charge trapping structure 120 may, in some examples, be between two portions of dielectric material 125. The transistor 110 also may include a first node 130 (e.g., a source or drain) and a second node 135 (e.g., a drain or source). A logic value may be stored in transistor 110 by storing (e.g., writing) a quantity of electrons (e.g., an amount of charge) on the charge trapping structure 120. An amount of charge to be stored on the charge trapping structure 120 may depend on the logic value to be stored. The charge stored on the charge trapping structure 120 may affect the threshold voltage of the transistor 110, thereby affecting the amount of current that flows through the transistor 110 when the transistor 110 is activated (e.g., when a voltage is applied to the control gate 115, when the memory cell 105-a is read). In some examples, the charge trapping structure 120 may be an example of a floating gate or a replacement gate that may be part of a 2D NAND structure. For example, a 2D NAND array may include multiple control gates 115 and charge trapping structures 120 arranged around a single channel (e.g., a horizontal channel, a vertical channel, a columnar channel, a pillar channel).

A logic value stored in the transistor 110 may be sensed (e.g., as part of a read operation) by applying a voltage to the control gate 115 (e.g., to control node 140, via a word line 165) to activate the transistor 110 and measuring (e.g., detecting, sensing) an amount of current that flows through the first node 130 or the second node 135 (e.g., via a bit line 155). For example, a sense component 170 may determine whether an SLC memory cell 105 stores a logic 0 or a logic 1 in a binary manner (e.g., based on a presence or absence of a current through the memory cell 105 when a read voltage is applied to the control gate 115, based on whether the current is above or below a threshold current). For a multiple-level memory cell 105, a sense component 170 may determine a logic value stored in the memory cell 105 based on various intermediate threshold levels of current when a read voltage is applied to the control gate 115, or by applying different read voltages to the control gate and evaluating different resulting levels of current through the transistor 110, or various combinations thereof. of a multiple-level architecture, a sense component 170 may determine the logic value of a TLC memory cell 105 based on eight different levels of current, or ranges of current, that define the eight potential logic values that could be stored by the TLC memory cell 105.

An SLC memory cell 105 may be written by applying one of two voltages (e.g., a voltage above a threshold or a voltage below a threshold) to the memory cell 105 to store, or not store, an electric charge on the charge trapping structure 120 and thereby cause the memory cell 105 to store one of two possible logic values. For example, when a first voltage is applied to the control node 140 (e.g., via a word line 165) relative to a bulk node 145 (e.g., a body node) for the transistor 110 (e.g., when the control node 140 is at a higher voltage than the bulk), electrons may tunnel into the charge trapping structure 120. Injection of electrons into the charge trapping structure 120 may be referred to as programming the memory cell 105 and may occur as part of a write operation. A programmed memory cell may, in some cases, be considered as storing a logic 0. When a second voltage is applied to the control node 140 (e.g., via the word line 165) relative to the bulk node 145 for the transistor 110 (e.g., when the control node 140 is at a lower voltage than the bulk node 145), electrons may leave the charge trapping structure 120. Removal of electrons from the charge trapping structure 120 may be referred to as erasing the memory cell 105 and may occur as part of an erase operation. An erased memory cell may, in some cases, be considered as storing a logic 1. In some cases, memory cells 105 may be programmed at a page level of granularity due to memory cells 105 of a page sharing a common word line 165, and memory cells 105 may be erased at a block level of granularity due to memory cells 105 of a block sharing commonly biased bulk nodes 145.

In contrast to writing an SLC memory cell 105, writing a multiple-level (e.g., MLC, TLC, or QLC) memory cell 105 may involve applying different voltages to the memory cell 105 (e.g., to the control node 140 or bulk node 145 thereof) at a finer level of granularity to more finely control the amount of charge stored on the charge trapping structure 120, thereby enabling a larger set of logic values to be represented. Thus, multiple-level memory cells 105 may provide greater density of storage relative to SLC memory cells 105 but may, in some cases, involve narrower read or write margins or greater complexities for supporting circuitry.

A charge-trapping NAND memory cell 105 may operate similarly to a floating-gate NAND memory cell 105 but, instead of or in addition to storing a charge on a charge trapping structure 120, a charge-trapping NAND memory cell 105 may store a charge representing a logic state in a dielectric material between the control gate 115 and a channel (e.g., a channel between a first node 130 and a second node 135). Thus, a charge-trapping NAND memory cell 105 may include a charge trapping structure 120, or may implement charge trapping functionality in one or more portions of dielectric material 125, among other configurations.

In some examples, each page of memory cells 105 may be connected to a corresponding word line 165, and each column of memory cells 105 may be connected to a corresponding bit line 155 (e.g., digit line). Thus, one memory cell 105 may be located at the intersection of a word line 165 and a bit line 155. This intersection may be referred to as an address of a memory cell 105. In some cases, word lines 165 and bit lines 155 may be substantially perpendicular to one another, and may be generically referred to as access lines or select lines.

In some cases, a memory device 100 may include a three-dimensional (3D) memory array, where multiple two-dimensional (2D) memory arrays may be formed on top of one another. In some examples, such an arrangement may increase the quantity of memory cells 105 that may be fabricated on a single die or substrate as compared with 1D arrays, which, in turn, may reduce production costs, or increase the performance of the memory array, or both. In the example of FIG. 1, memory device 100 includes multiple levels (e.g., decks, layers, planes, tiers) of memory cells 105. The levels may, in some examples, be separated by an electrically insulating material. Each level may be aligned or positioned so that memory cells 105 may be aligned (e.g., exactly aligned, overlapping, or approximately aligned) with one another across each level, forming a memory cell stack 175. In some cases, memory cells aligned along a memory cell stack 175 may be referred to as a string of memory cells 105 (e.g., as described with reference to FIG. 2).

Accessing memory cells 105 may be controlled through a row decoder 160 and a column decoder 150. For example, the row decoder 160 may receive a row address from the memory controller 180 and activate an appropriate word line 165 based on the received row address. Similarly, the column decoder 150 may receive a column address from the memory controller 180 and activate an appropriate bit line 155. Thus, by activating one word line 165 and one bit line 155, one memory cell 105 may be accessed. As part of such accessing, a memory cell 105 may be read (e.g., sensed) by sense component 170. For example, the sense component 170 may be configured to determine the stored logic value of a memory cell 105 based on a signal generated by accessing the memory cell 105. The signal may include a current, a voltage, or both a current and a voltage on the bit line 155 for the memory cell 105 and may depend on the logic value stored by the memory cell 105. The sense component 170 may include various circuitry (e.g., transistors, amplifiers) configured to detect and amplify a signal (e.g., a current or voltage) on a bit line 155. The logic value of memory cell 105 as detected by the sense component 170 may be output via input/output component 190. In some cases, a sense component 170 may be a part of a column decoder 150 or a row decoder 160, or a sense component 170 may otherwise be connected to or in electronic communication with a column decoder 150 or a row decoder 160.

A memory cell 105 may be programmed or written by activating the relevant word line 165 and bit line 155 to enable a logic value (e.g., representing one or more bits of information) to be stored in the memory cell 105. A column decoder 150 or a row decoder 160 may accept data (e.g., from the input/output component 190) to be written to the memory cells 105. In the case of NAND memory, a memory cell 105 may be written by storing electrons in a charge trapping structure or an insulating layer.

A memory controller 180 may control the operation (e.g., read, write, re-write, refresh) of memory cells 105 through the various components (e.g., row decoder 160, column decoder 150, sense component 170). In some cases, one or more of a row decoder 160, a column decoder 150, and a sense component 170 may be co-located with a memory controller 180. A memory controller 180 may generate row and column address signals in order to activate a desired word line 165 and bit line 155. In some examples, a memory controller 180 may generate and control various voltages or currents used during the operation of memory device 100.

In some cases, a manufacturing process to manufacture a memory device 100 may include a lateral wet etch to split a memory cell stack 175 into two memory cell stacks 175. In some cases, the manufacturing process may include forming a trench in a vertical stack of layers and forming a memory cell pillar which includes an oxide material (e.g., a gate oxide), a semiconductor channel material, and an insulating material in the trench. Sidewalls of the pillar may be laterally etched to remove portions of the oxide material and the semiconductor material, which may form two memory cell stacks 175, each memory cell stack 175 in contact with one of the opposing sidewalls of the trench. In some examples, the manufacturing process may include forming one or more supportive piers within the trench, and the pillar of memory cell material may be formed between pairs of piers, which may provide mechanical support to the pillar. Such methods may allow for fabrication of memory cells 105 with a reduced cell area (e.g., reduced by half) compared with GAA memory cells, while providing structural support to the memory cells 105 during fabrication.

FIG. 2 illustrates an example of a memory architecture 200 that supports methods to increase cell density using a lateral etch in accordance with examples as disclosed herein. The memory architecture 200 may be an example of a portion of a memory device, such as a memory device 100. Although some elements of a set of elements (e.g., an array of elements) are included in FIG. 2, some elements may be omitted for the sake of visibility and clarity of the depicted elements. Moreover, although some elements included in FIG. 2 are labeled with reference numbers, some other corresponding elements are not labeled, though they would be understood by a person having ordinary skill in the art to be the same as or similar to the labeled elements. Aspects of the memory architecture 200 may be described with reference to an x-direction, a y-direction, and a z-direction of the illustrated coordinate system.

The memory architecture 200 includes a three-dimensional array of memory cells 205, which may be examples of memory cells 105 described with reference to FIG. 1 (e.g., transistors 110, NAND memory cells). In some examples, the memory cells 205 may be connected in a 3D NAND configuration. For example, the memory cells 205 may be included in a block 210, which may be arranged as a 3D array of m memory cells along the x-direction, n memory cells along the y-direction, and o memory cells along the z-direction. Each memory cell 205 may be located (e.g., addressed) in accordance with an index i along the x-direction, an index j along the y-direction, and an index k along the z-direction (e.g., for locating a memory cell 205-a-ijk). A memory device 100 may include any quantity of one or more blocks 210 in accordance with examples as disclosed herein, and different blocks 210 may be adjacent along the x-direction, along the y-direction, or along the z-direction, or any combination thereof.

In the example of memory architecture 200, the block 210 may be divided into a set of pages 215 (e.g., a quantity of o pages 215) along the z-direction, including a page 215-a-1 associated with memory cells 205-a-111 through 205-a-mn1. In some examples, each page 215 may be associated with a same word line 265, (e.g., a word line 165 described with reference to FIG. 1), which may be coupled with a control gate 115 of each of the memory cells 205 of the page 215. For example, page 215-a-1 may be associated with a word line 265-a-1, and other pages 215-a-i may be associated with a different respective word line 265-a-i (not shown). In some examples, a word line 265 in accordance with the memory architecture 200 may be implemented as planar conductor (e.g., in an xy-plane) that is coupled with each of the memory cells 205 of the page 215.

In the example of memory architecture 200, the block 210 also may be divided into a set of strings 220 (e.g., a quantity of (m×n) strings 220) in an xy-plane, including a string 220-a-mn associated with memory cells 205-a-mn1 through 205-a-mno. In some examples, each string 220 may include a set of memory cells 205 connected in series (e.g., along the z-direction, in which a drain of one memory cell 205 in the string 220 may be coupled with a source of another memory cell 205 in the string 220). In some examples, memory cells 205 of a string 220 may be implemented along a common channel, such as a pillar channel (e.g., a columnar channel, a pillar of doped semiconductor) along the z-direction. Each memory cell 205 in a string 220 may be associated with a different word line 265, such that a quantity of word lines 265 in the memory architecture 200 may be equal to the quantity of memory cells 205 in a string 220. Accordingly, a string 220 may include memory cells 205 from multiple pages 215, and a page 215 may include memory cells 205 from multiple strings 220.

In some examples, memory cells 205 may be programmed (e.g., set to a logic 0 value) and read from in accordance with a granularity, such as at the granularity of a page 215 or portion thereof, but may not be erasable (e.g., reset to a logic 1 value) in accordance with the granularity, such as the granularity of a page 215 or portion thereof. For example, NAND memory may instead be erasable in accordance with a different (e.g., higher) level of granularity, such as at the level of granularity the block 210. In some cases, a memory cell 205 may be erased before it may be re-programmed. Different memory devices may have different read, write, or erase characteristics.

In some examples, each string 220 of a block 210 may be coupled with a respective transistor 230 (e.g., a string select transistor, a drain select transistor) at one end of the string 220 (e.g., along the z-direction) and a respective transistor 240 (e.g., a source select transistor, a ground select transistor) at the other end of the string 220. In some examples, a drain of each transistor 230 may be coupled with a bit line 250 of a set of bit lines 250 associated with the block 210, where the bit lines 250 may be examples of bit lines 155 described with reference to FIG. 1. A gate of each transistor 230 may be coupled with a select line 235 (e.g., a string select line, a drain select line). Thus, a transistor 230 may be used to couple a string 220 with a bit line 250 based on applying a voltage to the select line 235, and thus to the gate of the transistor 230. Although illustrated as separate lines along the x-direction, in some examples, select lines 235 may be common to all the transistors 230 associated with the block 210 (e.g., a commonly biased string select node). For example, like the word lines 265 of the block 210, select lines 235 associated with the block 210 may, in some examples, be implemented as a planar conductor (e.g., in an xy-plane) that is coupled with each of the transistors 230 associated with the block 210.

In some examples, a source of each transistor 240 associated with the block 210 may be coupled with a source line 260 of a set of source lines 260 associated with the block 210. In some examples, the set of source lines 260 may be associated with a common source node (e.g., a ground node) corresponding to the block 210. A gate of each transistor 240 may be coupled with a select line 245 (e.g., a source select line, a ground select line). Thus, a transistor 240 may be used to couple a string 220 with a source line 260 based on applying a voltage to the select line 245, and thus to the gate of the transistor 240. Although illustrated as separate lines along the x-direction, in some examples, select lines 245 also may be common to all the transistors 240 associated with the block 210 (e.g., a commonly biased ground select node). For example, like the word lines 265 of the block 210, select lines 245 associated with the block 210 may, in some examples, be implemented as a planar conductor (e.g., in an xy-plane) that is coupled with each of the transistors 240 associated with the block 210.

To operate the memory architecture 200 (e.g., to perform a program operation, a read operation, or an erase operation on one or more memory cells 205 of the block 210), various voltages may be applied to one or more select lines 235 (e.g., to the gate of the transistors 230), to one or more bit lines 250 (e.g., to the drain of one or more transistors 230), to one or more word lines 265, to one or more select lines 245 (e.g., to the gate of the transistors 240), to one or more source lines 260 (e.g., to the source of the transistors 240), or to a bulk for the memory cells 205 (not shown) of the block 210. In some cases, each memory cell 205 of a block 210 may have a common bulk, the voltage of which may be controlled independently of bulks for other blocks 210.

In some cases, as part of a read operation for a memory cell 205, a positive voltage may be applied to the corresponding bit line 250 while the corresponding source line 260 may be grounded or otherwise biased at a voltage lower than the voltage applied to the bit line 250. In some examples, voltages may be concurrently applied to the select line 235 and the select line 245 that are above the threshold voltages of the transistor 230 and the transistor 240, respectively, for the memory cell 205, thereby activating the transistor 230 and transistor 240 such that a channel associated with the string 220 that includes the memory cell 205 (e.g., a pillar channel) may be electrically connected with (e.g., electrically connected between) the corresponding bit line 250 and source line 260. A channel may be an electrical path through the memory cells 205 in the string 220 (e.g., through the sources and drains of the transistors in the memory cells 205 of the string 220) that may conduct current under some operating conditions.

In some examples, multiple word lines 265 (e.g., in some cases all word lines 265) of the block 210—except a word line 265 associated with a page 215 of the memory cell 205 to be read—may concurrently be set to a voltage (e.g., VREAD) that is higher than the threshold voltage (VT) of the memory cells 205. VREAD may cause all memory cells 205 in the unselected pages 215 be activated so that each unselected memory cell 205 in the string 220 may maintain high conductivity within the channel. In some examples, the word line 265 associated with the memory cell 205 to be read may be set to a voltage, VTarget. Where the memory cells 205 are operated as SLC memory cells, VTarget may be a voltage that is between (i) VT of a memory cell 205 in an erased state and (ii) VT of a memory cell 205 in a programmed state.

When the memory cell 205 to be read exhibits an erased VT (e.g., VTarget>VT of the memory cell 205), the memory cell 205 may turn “ON” in response to the application of VTarget to the word line 265 of the selected page 215, which may allow a current to flow in the channel of the string 220, and thus from the bit line 250 to the source line 260. When the memory cell 205 to be read exhibits a programmed VT (e.g., VTarget<VT of the selected memory cell), the memory cell 205 may remain “OFF” despite the application of VTarget to the word line 265 of the selected page 215, and thus may prevent a current from flowing in the channel of the string 220, and thus from the bit line 250 to the source line 260.

A signal on the bit line 250 for the memory cell 205 (e.g., an amount of current below or above a threshold) may be sensed (e.g., by a sense component 170 as described with reference to FIG. 1), and may indicate whether the memory cell 205 became conductive or remained non-conductive in response to the application of VTarget to the word line 265 of the selected page 215. The sensed signal thus may be indicative of whether the memory cell 205 was in an erased state (e.g., storing a logic 1) or a programmed state (e.g., storing a logic 0). Though aspects of the example read operation above have been explained in the context of an SLC memory cell 205 for clarity, such techniques may be extended or altered and applied in the context of a multiple-level memory cell 205 (e.g., through the use of multiple values of VTarget corresponding to the different amounts of charge that may be stored in one multiple-level memory cell 205).

In some cases, as part of a program operation for a memory cell 205, charge may be added to a portion of the memory cell 205 such that current flow through the memory cell 205, and thus the corresponding string 220, may be inhibited when the memory cell 205 is later read. For example, charge may be injected into a charge trapping structure 120 as shown in memory cell 105-a of FIG. 1. In some cases, respective voltages may be applied to the word line 265 of the page 215 and the bulk of the memory cell 205 to be programmed such that a control gate 115 of the memory cell 205 is at a higher voltage than the bulk of the memory cell 205 (e.g., a positive voltage may be applied to the word line). Concurrently, voltages may be applied to the select line 235 and the select line 245 that are above the threshold voltages of the transistor 230 and the transistor 240, respectively, thereby activating the transistor 230 and the transistor 240, and the bit line 250 for the memory cell 205 to be programmed may be set to a relatively high voltage. This may cause an electric field such that electrons are pulled from the source of the memory cell 205 towards the drain. The electric field may also cause some of these electrons to be pulled through dielectric material 125 and thereby injected into the charge trapping structure 120 of the memory cell 205, through a process which may in some cases be referred to as tunnel injection.

In some cases, a single program operation may program some or all memory cells 205 in a page 215, as the memory cells 205 of the page 215 may all share a common word line 265 and a common bulk. For a memory cell 205 of the page 215 for which it is not desired to write a logic 0 (e.g., not desired to program the memory cell 205), the corresponding bit line 250 may be set to a relatively low voltage (e.g., ground), which may inhibit the injection of electrons into a charge trapping structure 120. Though aspects of the example program operation above have been explained in the context of an SLC memory cell 205 for clarity, such techniques may be extended and applied to the context of a multiple-level memory cell 205 (e.g., through the use of multiple programming voltages applied to the word line 265, or multiple passes or pulses of a programming voltage applied to the word line 265, corresponding to the different amounts of charge that may be stored in one multiple-level memory cell 205).

In some cases, as part of an erase operation for a memory cell 205, charge may be removed from a portion of the memory cell 205 such that current flow through the memory cell 205, and thus the corresponding string 220, may be uninhibited (e.g., allowed, at least to a greater extent) when the memory cell 205 is later read. For example, charge may be removed from a charge trapping structure 120 as shown in memory cell 105-a of FIG. 1. In some cases, respective voltages may be applied to the word line 265 of the page 215 and the bulk of the memory cell 205 to be erased such that a control gate 115 of the memory cell 205 is at a lower voltage than the bulk of the memory cell 205 (e.g., a positive voltage may be applied to the bulk), which may cause an electric field that pulls electrons out of the charge trapping structure 120 and into the bulk of the memory cell 205. In some cases, a single program operation may erase all memory cells 205 in a block 210, as the memory cells 205 of the block 210 may all share a common bulk.

In some cases, a manufacturing process to manufacture a memory array with the memory architecture 200 may include a lateral wet etch to split a memory cell stack into two memory cell strings 220. In some cases, the manufacturing process may include forming a trench in a vertical stack of layers and forming a memory cell pillar which includes an oxide material (e.g., a gate oxide), a semiconductor channel material, and an insulating material in the trench. Sidewalls of the pillar may be laterally etched to remove portions of the oxide material and the semiconductor material, which may form two strings 220, each string 220 in contact with one of the opposing sidewalls of the trench. In some examples, the manufacturing process may include forming one or more supportive piers within the trench, and the pillar of memory cell material may be formed between pairs of piers, which may provide mechanical support to the pillar. Such methods may allow for fabrication of memory cells 205 with a reduced cell area (e.g., reduced by half) compared with GAA memory cells, while providing structural support to the memory cells 205 during fabrication.

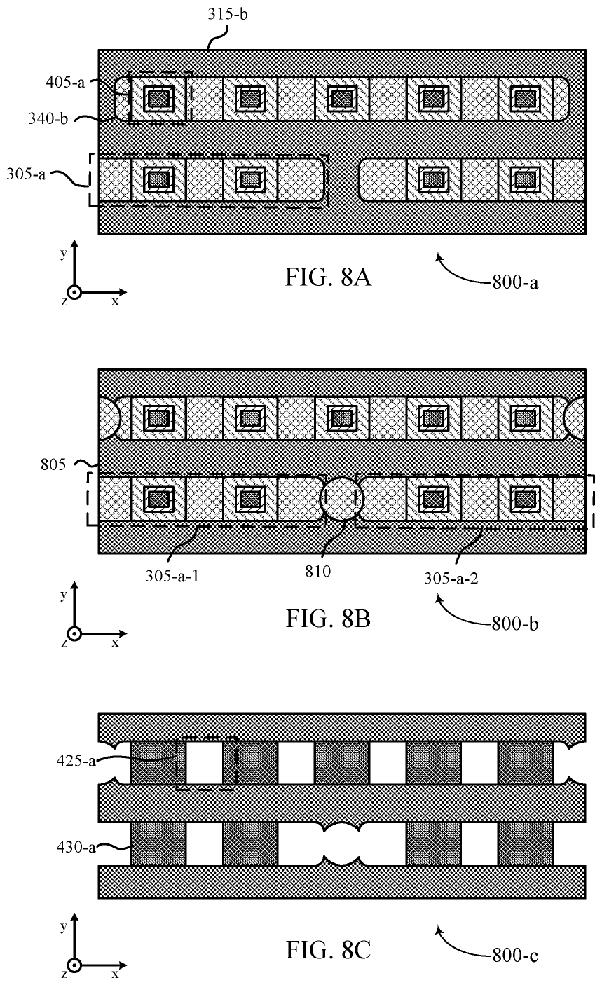

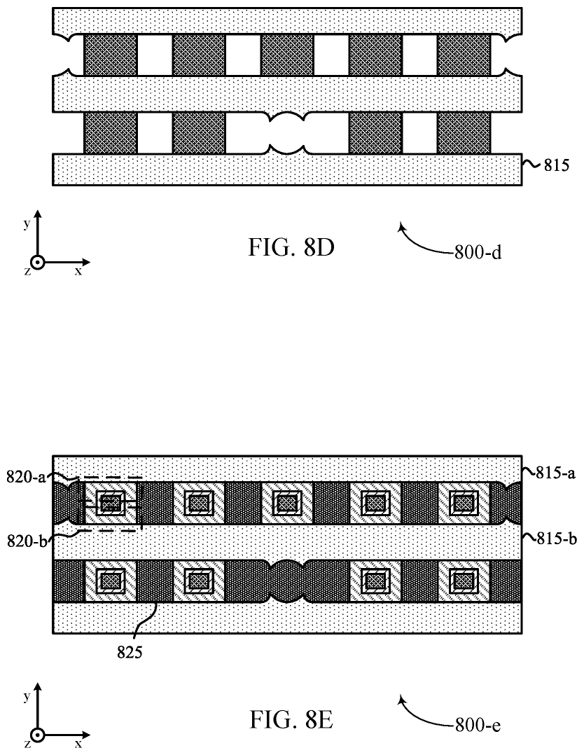

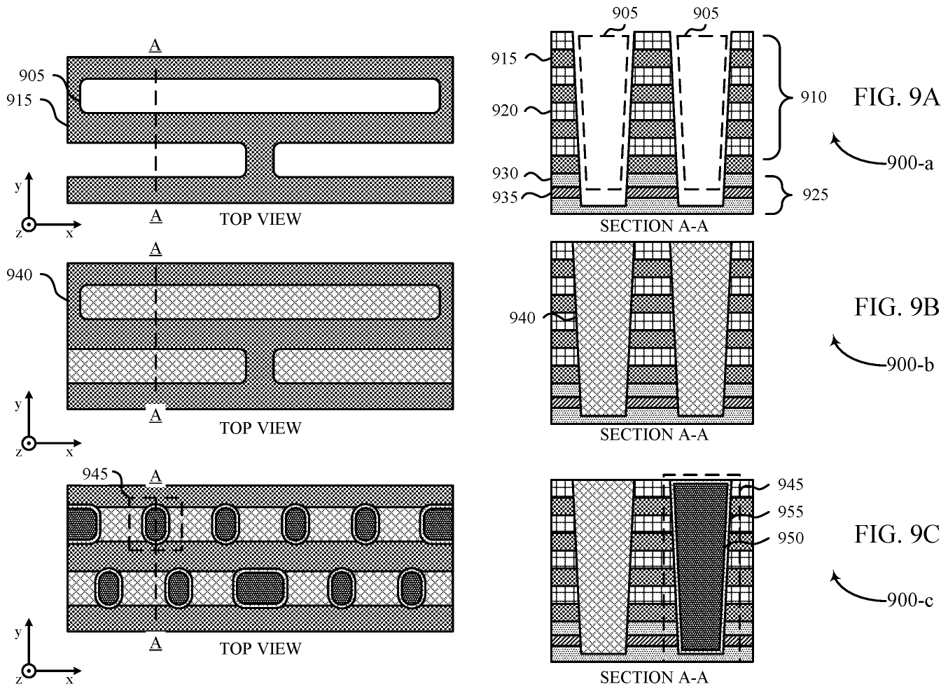

FIGS. 3A through 12 illustrate examples of operations and memory arrays that support methods to increase cell density using a lateral etch in accordance with examples as disclosed herein. For example, FIGS. 3A through 7E may illustrate aspects of a sequence of operations for fabricating aspects of a first memory array, which may be a portion of a memory device (e.g., a portion of a memory device, a portion of a memory die), FIGS. 8A through 8E may illustrate aspects of a sequence of operations for fabricating aspects of a second memory array, and FIGS. 9A through 12 may illustrate aspects of a sequence of operations for fabricating aspects of a third memory array. Each view of the figures may be described with reference to an x-direction, a y-direction, and a z-direction, as illustrated. The provided figures may include section views that illustrate example cross-sections of the memory array. For example, in FIGS. 3A through 12, a view “SECTION A-A” may be associated with a cross-section in an yz-plane (e.g., in accordance with a cut plane A-A), and a view “SECTION B-B” may be associated with a cross-section in an xz-plane (e.g., in accordance with a cut plane B-B). Further, a view “SECTION C-C” may be associated with a cross-section in a vertical cut plane C-C. Additionally, a top view may be associated with a cross-section in an xy-plane. Although FIGS. 3A through 12 illustrates examples of certain relative dimensions and quantities of various features, aspects of the illustrated memory arrays may be implemented with other relative dimensions or quantities of such features in accordance with examples as disclosed herein.

Operations illustrated in and described with reference to FIGS. 3A through 12 may be performed by a manufacturing system, such as a semiconductor fabrication system configured to perform additive operations such as deposition or bonding, subtractive operations such as etching (e.g., dry etching, wet etching, lateral etching), trenching, planarizing, or polishing, and supporting operations such as masking, patterning, photolithography, or aligning, among other operations that support the described techniques. In some examples, operations performed by such a manufacturing system may be supported by a process controller or its components as described herein.

FIG. 3A illustrates an example of a memory array 300-a after a set of manufacturing operations that supports methods to increase cell density using a lateral etch in accordance with examples as disclosed herein. The set of manufacturing operations may include operations that support forming one or more trenches 305 in a vertical stack of layers 310. For example, the set of manufacturing operations may include depositing alternating layers of a first material 315, such as a nitride material, and a second material 320, such as an oxide material or other dielectric or insulating material, to form the vertical stack of layers 310. In some cases, the first material 315, the second material 320, or both may be selective to a material removal process, such as a wet etch. For example, the first material 315 may be substantially removed using the wet etch, while the second material 320 may be substantially preserved by the wet etch (e.g., the wet etch may be selective to the first material 315).

In some cases, the vertical stack of layers 310 may be formed over a substrate 325. In such cases, the set of manufacturing operations may further support depositing or otherwise forming the substrate 325 (e.g., forming one or more layers of the substrate 325). The substrate 325 may include a layer of a semiconductor material 330 disposed between multiple (e.g., two) layers of a semiconductor material 335. The semiconductor material 330 may be deposited as an undoped semiconductor material, such as undoped polysilicon, and the semiconductor material 330 may be deposited as a doped semiconductor material, such as polysilicon doped with boron or other dopants, such that the semiconductor material 330 may be an example of a p-type semiconductor material (e.g., p-type polysilicon). In some examples, each layer of the semiconductor material 330 may include a layer of oxide material between the layer of the semiconductor material 330 and the semiconductor material 335.

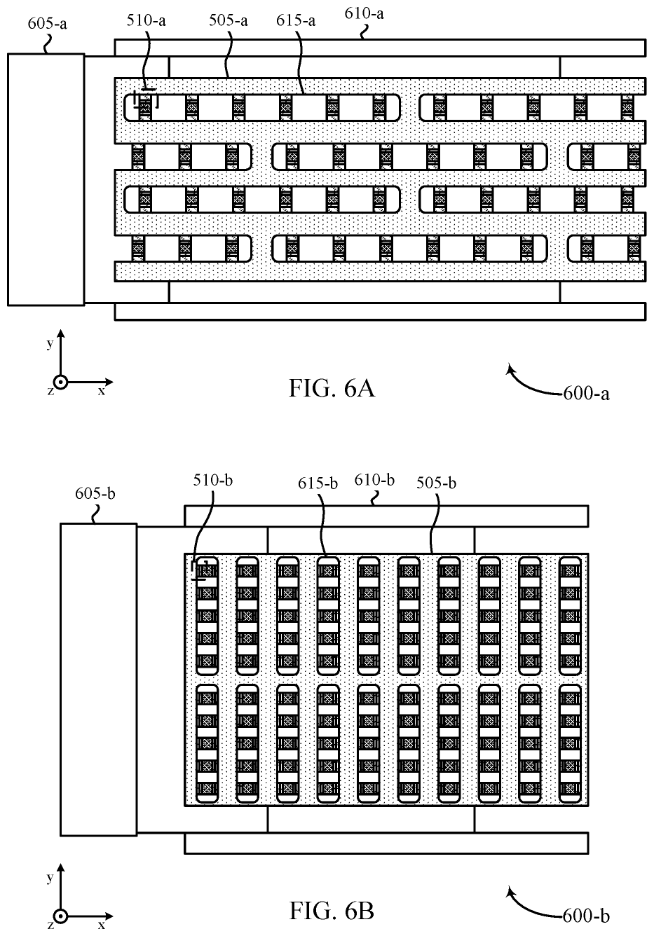

The set of manufacturing operations may include etching (e.g., dry etching) the vertical stack of layers 310 and, in some cases, at least a portion of the layered substrate 325 to remove material from the vertical stack of layers 310, the layered substrate 325, or both to form the one or more trenches 305, which may be examples of cavities or voids within the vertical stack of layers 310. In some cases, the one or more trenches 305 may extend in the x-direction, as illustrated in FIG. 3A and described in greater detail with reference to FIG. 6A. Alternatively, the one or more trenches 305 may extend in the y-direction, as described in greater detail with reference to FIG. 6B.

The aspect ratio of each of the one or more trenches 305 (e.g., that ratio between the length of a trench 305 in a first horizontal direction and the length of the trench 305 in a second horizontal direction) may be selected to be less than a threshold quantity. For example, to support mechanical stability of a trench 305, the aspect ratio of a trench 305 may be less than a quantity N, where N may be between 10 and 20, in accordance with the specific materials selected for the first material 315 and the second material 320.

FIG. 3B illustrates an example of a memory array 300-b after a second set of manufacturing operations that supports methods to increase cell density using a lateral etch in accordance with examples as disclosed herein. The second set of manufacturing operations may include operations that support filling the one or more trenches 305 with a placeholder material 340. For example, the second set of manufacturing operations may include depositing the placeholder material 340 within the one or more trenches 305 to fill (e.g., fully fill, at least partially fill) the voids associated with the one or more trenches 305. In some examples, the placeholder material 340 may be a sacrificial material, such as a sacrificial polysilicon material, a nitride material, an aluminum oxide material, a doped semiconductor material, or a combination thereof.

FIG. 3C illustrates an example of a memory array 300-c after a third set of manufacturing operations that supports methods to increase cell density using a lateral etch in accordance with examples as disclosed herein. The third set of manufacturing operations may include operations that support forming one or more cavities 345 in the one or more trenches 305. For example, the second set of manufacturing operations may include etching (e.g., dry etching, anisotropic deep etching) the placeholder material 340 to remove portions of the placeholder material 340 to form the one or more cavities 345. In some examples, the one or more cavities may expose a portion of the layered substrate 325, such as the semiconductor material 330, the semiconductor material 335, or both. The one or more cavities 345 may define one or more pillars 350 of the placeholder material 340, such that each cavity 345 exposes a sidewall of one or more pillars 350. The one or more cavities 345 may be arranged in a grid-like rectangular pattern, as illustrated in FIG. 3C, or may be arranged in a hexagonal pattern (e.g., staggered between adjacent trenches 305).

In some examples, the one or more cavities 345 may be rectilinear, as illustrated in FIG. 3C. Alternatively, the one or more cavities 345 may be rounded (e.g., the one or more cavities may be recessed) into the one or more pillars 350, beyond the one or more trenches 305, or both. In some cases, rounding into the one or more pillars may increase the width of a cell gate of one or more memory cells formed within the one or more cavities 345. Additionally, rounding beyond the one or more trenches may cause a memory cell formed within the one or more cavities 345 to similarly rounded, which may improve channel control of one or more memory cells formed within the one or more cavities 345.

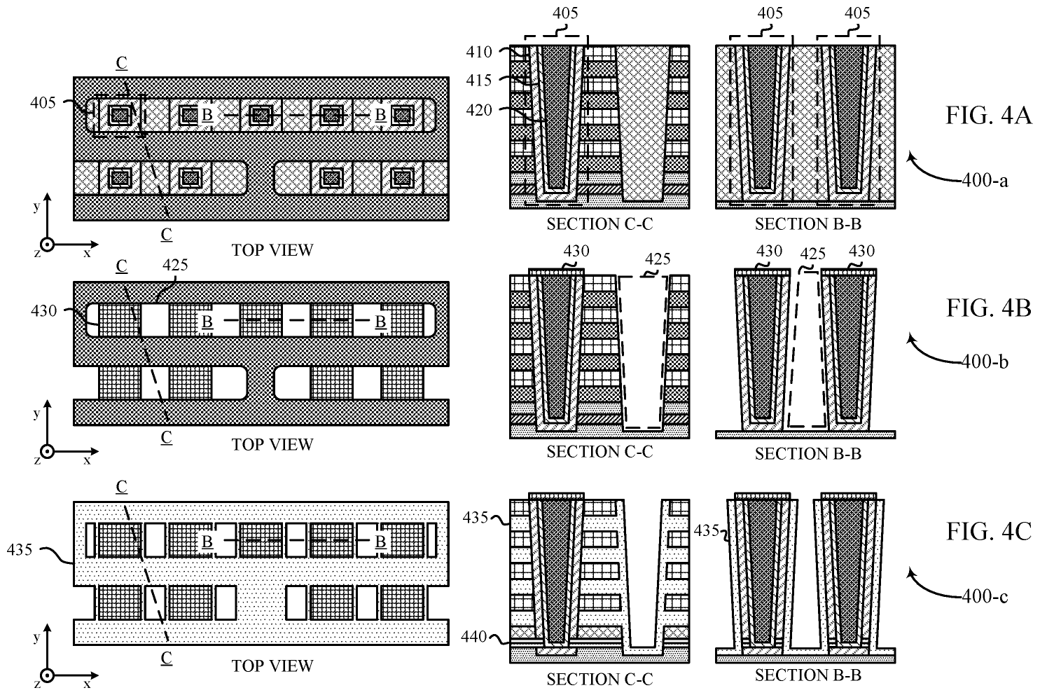

FIG. 4A illustrates an example of a memory array 400-a after a fourth set of manufacturing operations that supports methods to increase cell density using a lateral etch in accordance with examples as disclosed herein. The fourth set of manufacturing operations may include operations that support forming one or more pillars 405 in the one or more cavities 345. For example, the fourth set of manufacturing operations may include depositing a material 410 within each of the one or more cavities 345 to contact exposed portions of the sidewalls of the pillars 350, exposed portions or the layered substrate 325 (e.g., the semiconductor material 330, the semiconductor material 335), or both. In some examples, the material 410 may be an example of an insulating material, such as an oxide material. Additionally or alternatively, the material 410 may be an example of a doped semiconductor material, such as a polysilicon or silicon glass material heavily doped with boron or phosphorous.

The fourth set of manufacturing operations may further include depositing a semiconductor material 415 in the one or more cavities 345 in contact with the material 410. The semiconductor material 415 may be an example of a polysilicon channel material, which may act as a channel for one or more transistors associated with each pillar 405. For example, the semiconductor material 415 may be an undoped or lightly doped polysilicon, such as a doped hollow channel (DHC) material.

The fourth set of manufacturing operations may further include depositing an insulating material 420 in the one or more cavities 345 in contact with the semiconductor material 415. The insulating material 420 may be an example of an oxide or other dielectric material, and may provide mechanical support to a pillar 405. In some examples, the insulating material 420 may be selective to a material removal process (e.g., a wet etch), such that removal process may remove the insulative material 420 while preserving the material 410 and the semiconductor material 415.

FIG. 4B illustrates an example of a memory array 400-b after a fifth set of manufacturing operations that supports methods to increase cell density using a lateral etch in accordance with examples as disclosed herein. The fifth set of manufacturing operations may include operations that support forming one or more cavities 425 in the vertical stack of layers 310. For example, the set of manufacturing operations may include exhuming the remaining sacrificial material 340 (e.g., the sacrificial material 340 remaining after forming the pillars 405) to form the one or more cavities 425. Each cavity 425 may expose a sidewall of one or more pillars 405 (e.g., the material 410 of each pillar 405). In some examples, prior to forming the one or more cavities 425, the fifth set of manufacturing operations may include forming a cap 430 on each of the pillars 405, which may protect the pillars 405 during the exhuming process (e.g., may prevent or reduce the removal of materials of the pillars 405 while exhuming the placeholder material 340).

FIG. 4C illustrates an example of a memory array 400-c after a sixth set of manufacturing operations that supports methods to increase cell density using a lateral etch in accordance with examples as disclosed herein. The sixth set of manufacturing operations may include operations that support forming a conductive material 435 within the vertical stack of layers 310. For example, the sixth set of manufacturing operations may include removing the material 315 from the vertical stack of layers 310, such as by using a material removal process selective to the material 315 (e.g., a wet etch), to form one or more voids between layers of the material 320. The sixth set of manufacturing operations may further include depositing the conductive material 435 to fill the one or more voids.

In some examples, the sixth set of manufacturing instructions may further include doping the semiconductor material 335 to form a doped semiconductor material 440. The doped semiconductor material 440 may be an example of an n-type semiconductor, such as n-type polysilicon. In some cases, doping the semiconductor material 335 may include exposing the semiconductor material 335 to a dopant gas (e.g., in-sutu doping), depositing a doped silicon glass on the semiconductor material 335 (e.g., diffusion doping), exposing the semiconductor material 335 to high-energy ions (e.g., ion implantation), or a combination thereof.

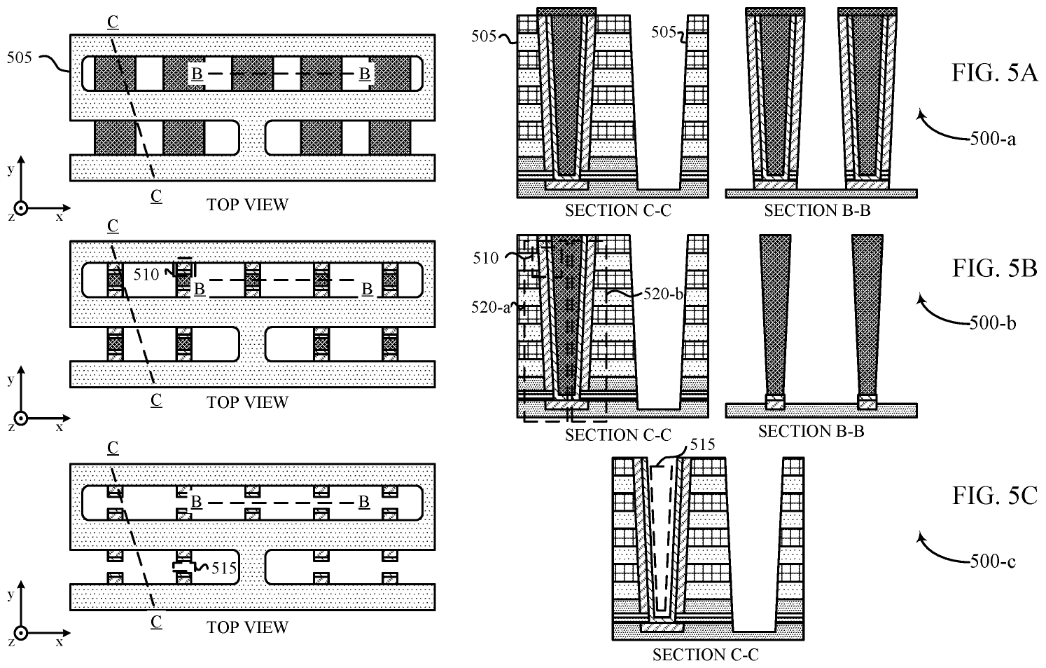

FIG. 5A illustrates an example of a memory array 500-a after a seventh set of manufacturing operations that supports methods to increase cell density using a lateral etch in accordance with examples as disclosed herein. The seventh set of manufacturing operations may include operations that support forming one or more word line plates 505 within the vertical stack of layers 310. For example, the seventh set of manufacturing operations may include removing a portion of the conductive material 435 from the vertical stack of layers 310, for example using an etching or etch-back operation. In some cases, removing the portion of the conductive material 435 may expose one or more sidewalls of the pillars 405. Additionally, removing the portion of the conductive material 435 may electrically isolate each word line plate 505 from other word line plates 505.

FIG. 5B illustrates an example of a memory array 500-b after an eighth set of manufacturing operations that supports methods to increase cell density using a lateral etch in accordance with examples as disclosed herein. The eighth set of manufacturing operations may include operations that support forming one or more memory cells 510 from each of the one or more pillars 405. For example, the eighth set of manufacturing operations may include using a lateral etch (e.g., lateral wet etch) to remove a portion of the material 410 and a portion of the semiconductor material 415 from one or more sidewalls of each pillar 405, which may expose the insulating material 420 of each pillar 405. Accordingly, each memory cell 510 may be formed on a respective sidewall of the trench 305. For example, each memory cell 510 may include a floating gate in-between a word line plate 505 and a channel, where the channel extends vertically in the trench to contact a bit line below the stack of materials (e.g., via a switching device).

FIG. 5C illustrates an example of a memory array 500-c after a ninth set of manufacturing operations that supports methods to increase cell density using a lateral etch in accordance with examples as disclosed herein. The ninth set of manufacturing operations may include operations that remove the insulating material 420 to form a gap 515 (e.g., a void) between adjacent pairs of memory cells. For example, the ninth set of manufacturing operations may include etching or exhuming the insulative material 420 to form the one or more gaps 515 (e.g., one or more air gaps). Because the dielectric constant of a fluid (e.g., air) which may fill the gaps 515 may be lower than the dielectric constant of the insulating material 420, the gaps 515 may reduce interference between pairs of memory cells 510 on opposing sidewalls of a trench 305, such as by reducing capacitance between the adjacent pairs of memory cells.

The memory array 500-c may undergo additional manufacturing operations to incorporate the one or more memory cells 510 into a memory device, such as a memory device using the memory architecture 200 as described with reference to FIG. 2. For example, a memory cell 510 may be an example of a memory cell 205, and may be an example of a transistor that includes a charge trapping structure, such as the material 410. Each memory cell 510 or layer of memory cells 510 may be coupled with a respective word line plate 505, which may an example of the word lines 265. Additionally, memory cells 510 formed from a same side of a pillar 405 (e.g., a vertical stack of memory cells 510) may be coupled together as a string of memory cells 520, which may be an example of a string 220.

In some cases, a string of memory cells 520 may be coupled with a bit line 250, a source line 260, or both using one or more selecting transistors, such as thin-film transistors (TFTs), to support operation of the memory device. For example, the memory array 500-c may include an array of switching components (e.g., TFTs, transistors) below the layered substrate 325, which may selectively couple the strings of memory cells 520 (e.g., using a select line 235 to activate one or more switching components) with one or more bit lines. Accordingly, a memory cell 510 in a given string of memory cells 520 and at a given layer may be accessed by activating the switching component and, in some cases, the bit line, associated with the given string of memory cells 520 and by activating the word line plate 505 at the given layer.

In some examples, strings of memory cells 520 formed from a same pillar 405, such as the string of memory cells 520-a and the string of memory cells 520-b, may be selectively coupled with a same bit line using respective switching components to multiplex signals between the strings of memory cells 520 and the bit line. Alternatively, the string of memory cells 520-a and the string of memory cells 520-b may each be selectively coupled with a separate bit line.

FIG. 6A illustrates an example of a memory array 600-a that supports methods to increase cell density using a lateral etch in accordance with examples as disclosed herein. The memory array 600-a may include aspects of a memory array manufactured using a set of manufacturing operations as described with reference to FIGS. 3A through 5C. For example, the memory array 600-a may include a layered stack of word line plates 505-a arranged along a vertical direction (e.g., along the z-direction), which may each be coupled with one or more memory cells 510-a.

The memory array 600-a may support operations to access the memory cells 510-a using a word line driver coupled with a word line staircase 605-a. The word line staircase 605-a may be an example of or may include a set of vias which couple with one or more contacts of each word line plate 505-a. To support such coupling, the word line plates 505-a may be arranged in a staircase structure, which may expose to contacts of each word line plate 505-a. The set of vias may further couple with one or more drivers which may drive the word line plates 505-a.

The memory cells 510-a of the memory array 600-a may be disposed along sidewalls of one or more trenches 615-a, which may be examples of the one or more trenches 305 as described with reference to FIG. 3A. In some cases, each of the one or more trenches 305 may extend along the first horizontal direction parallel to slots 610-a (e.g., may extend in the x-direction). That is, the length of a trench 615-a in the first horizontal direction may be greater than the length of the trench 615-a in a second horizontal direction (e.g., in the y-direction).

In some examples, the memory cells 510-a illustrated in FIG. 6A may be included in a block of memory cells 510-a of the memory array 600-a. In such examples, the memory array 600-a may include additional blocks of memory cells 510-a, which may be separated from the block of memory cells 510-a illustrated in FIG. 6A by one or more slots 610-a (e.g., one or more voids), which may extend in a first horizontal direction (e.g., the x-direction), parallel to a word line direction. The slots 610-a may separate each word line plate 505-a from adjacent word line plates 505-a (e.g., in the y direction). In some examples, the slots 610-a in-between blocks of memory cells 510-a may be used for a replacement gate process for forming the memory cells 510-a (e.g., may be used to replace one or more sacrificial materials such as in a layered stack of materials).

FIG. 6B illustrates an example of a memory array 600-b that supports methods to increase cell density using a lateral etch in accordance with examples as disclosed herein. The memory array 600-b may include aspects of the memory array 600-a, such as one or more word line plates 505-b, one or more memory cells 510-b, a word line staircase 605-b, and one or more slots 610-b extending in the first horizontal direction.

Additionally, the memory array 600-b may include one or more trenches 615-b in which the one or more memory cells 510-b may be disposed. In some cases, each of the one or more trenches 615-b may extend along the second horizontal direction perpendicular to the slots 610-b (e.g., may extend in the y-direction). That is, length of a trench 615-b in the second horizontal direction may be greater than the length of the trench 615-b in the first horizontal direction.

In some examples, the memory cells 510-b illustrated in FIG. 6B may be included in a block of memory cells 510-b of the memory array 600-b. In such examples, the memory array 600-b may include additional blocks of memory cells 510-b, which may be separated from the block of memory cells 510-b illustrated in FIG. 6B by one or more slots 610-b, which may extend in the first horizontal direction, parallel to the word lines. The slots 610-b may separate each word line plate 505-b from adjacent word line plates 505-b (e.g., in the y direction). In some examples, the slots 610-b in-between blocks of memory cells 510-b may be used for a replacement gate process for forming the memory cells 510-b (e.g., may be used to replace one or more sacrificial materials such as in a layered stack of materials).

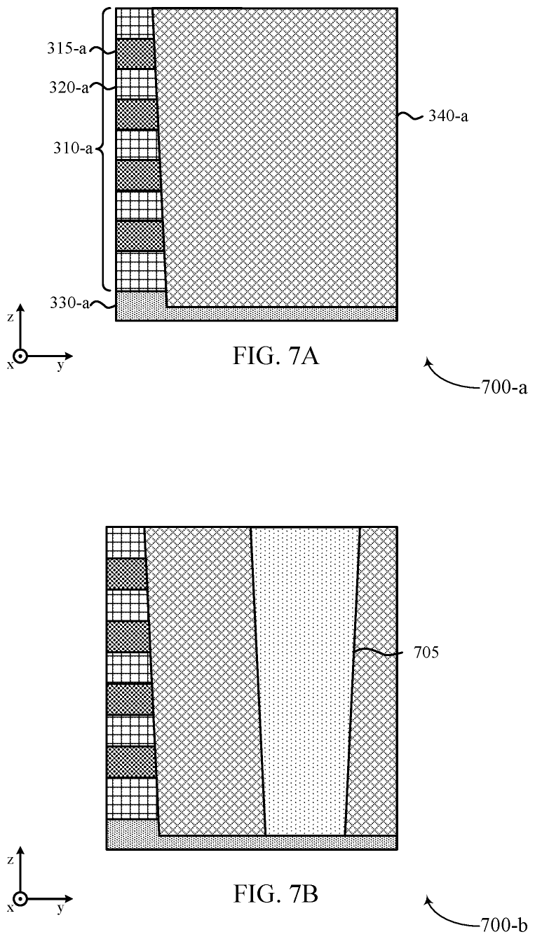

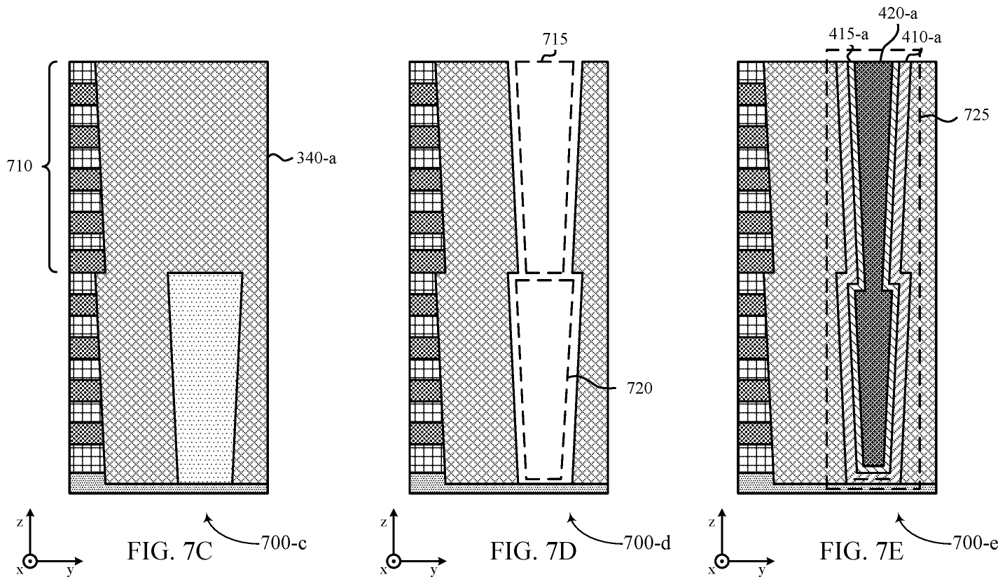

FIGS. 7A through 7E illustrate examples of a set of manufacturing operations performed on a memory array, such as the memory arrays as described with reference to FIGS. 3A through 5C, to form multiple decks of the memory array. FIG. 7A illustrates an example of a memory array 700-a after a set of manufacturing operations that supports methods to increase cell density using a lateral etch in accordance with examples as disclosed herein. The memory array 700-a may include aspects of the memory array 300-b, as described with reference to FIG. 3B.

For example, the memory array 700-a may include a vertical stack of layers 310-a having alternating layers of a material 315-a and a material 320-a and disposed on a substrate, which may include a semiconductor material 330-a. One or more trenches (e.g., one or more trenches 305) may be formed within the vertical stack of layers 310-a, and each of the one or more trenches may be filled with a placeholder material 340-a. Accordingly, the memory array 700-a may be the same or similar to the memory array 300-b, and the set of manufacturing operations used to form the memory array 700-a may be the same or similar to the set of manufacturing operations used to form the memory array 300-b.

FIG. 7B illustrates an example of a memory array 700-b after a second set of manufacturing operations that supports methods to increase cell density using a lateral etch in accordance with examples as disclosed herein. The second set of manufacturing operations may support forming one or more pillars 705 within the placeholder material 340-a, which may provide mechanical support for the memory array 700-b during subsequent manufacturing operations. For example, the second set of manufacturing operations may include forming one or more cavities in the placeholder material 340-a. In some cases, the one or more cavities may be formed using a process similar to forming the one or more cavities 345 as described with reference to FIG. 3C.

The second set of manufacturing operations may additionally include depositing a second placeholder material within the one or more cavities to form the one or more pillars 705. In some examples, the placeholder material 340-a and the second placeholder material may be different sacrificial materials, and may be selective to different material removal processes. For example, an etching process to remove the second placeholder material may preserve the placeholder material 340-a.

FIG. 7C illustrates an example of a memory array 700-c after a third set of manufacturing operations that supports methods to increase cell density using a lateral etch in accordance with examples as disclosed herein. The third set of manufacturing operations may support forming a vertical stack of layers 710 above the vertical stack of layers 310-a. For example, the third set of manufacturing operations may include depositing alternating layers of the material 315-a and the material 320-a above the vertical stack of layers 310-a to form the vertical stack of layers 710. The third set of manufacturing operations may further include removing portions of the vertical stack of layers 710 to form one or more trenches positioned above the one or more trenches of the vertical stack of layers 310-a. Additionally, the third set of manufacturing operations may include depositing the placeholder material 340-a within the one or more trenches of the vertical stack of layers 710, which may cover the second placeholder material of the pillar 705.

FIG. 7D illustrates an example of a memory array 700-d after a fourth set of manufacturing operations that supports methods to increase cell density using a lateral etch in accordance with examples as disclosed herein. The fourth set of manufacturing operations may support forming one or more cavities 715 within the vertical stack of layers 710 and forming one or more cavities 720 within the vertical stack of layers 310-a.

For example, the fourth set of manufacturing operations may include etching (e.g., dry etching, anisotropic deep etching) the placeholder material 340-a of the vertical stack of layers 710 to remove portions of the placeholder material 340-a and form the one or more cavities 715. In some examples, the one or more cavities 715 may expose a portion, such as an upper surface, of the pillar 705. The fourth set of manufacturing operations may further include removing the second placeholder material of the pillar 705 exposed by the one or more cavities 715. For example, the fourth set of manufacturing operations may include exhuming the second placeholder material (e.g., using a wet etch selective to the second place holder material) to form the one or more cavities 720. In some examples, the one or more cavities 720 may expose a portion (e.g., an upper surface) of the semiconductor material 330-a.

FIG. 7E illustrates an example of a memory array 700-e after a fifth set of manufacturing operations that supports methods to increase cell density using a lateral etch in accordance with examples as disclosed herein. The fifth set of manufacturing operations may include operations that support forming one or more pillars 725 in the one or more cavities 715, the one or more cavities 720, or both. In some cases, the one or more pillars 725 may include aspects of the one or more pillars 405 as described with reference to FIG. 4A.

For example, the fifth set of manufacturing operations may include depositing a material 410-a within each of the one or more cavities 715 and each of the one or more cavities 720 to contact exposed portions of the semiconductor material 330-a. The fifth set of manufacturing operations may further include depositing a semiconductor material 415-a in each of the one or more cavities 715 and each of the one or more cavities 720 in contact with the material 410-a, and depositing an insulating material 420-a in each of the one or more cavities 715 and each of the one or more cavities 720 in contact with the semiconductor material 415-a.

FIGS. 8A through 8E illustrate examples of a set of manufacturing operations performed on a memory array, such as the memory arrays as described with reference to FIGS. 3A through 5C, to form a split word lines within a memory array. FIG. 8A illustrates an example of a memory array 800-a that supports methods to increase cell density using a lateral etch in accordance with examples as disclosed herein. The memory array 800-a may include aspects of the memory array 400-a, as described with reference to FIG. 4A.

For example, the memory array 800-a may include a vertical stack of layers having alternating layers of the material 315-b and the material 320. One or more trenches 305-a may be formed within the vertical stack of layers, and each of the one or more trenches 305-a may be filled with a placeholder material 340-b. Additionally, one or more pillars 405-a may be disposed within each of the one or more trenches 305-a. Accordingly, the memory array 800-a may be the same or similar to the memory array 400-a, and the set of manufacturing operations used to form the memory array 800-a may be the same or similar to the set of manufacturing operations used to form the memory array 400-a.

FIG. 8B illustrates an example of a memory array 800-b after a second set of manufacturing operations that supports methods to increase cell density using a lateral etch in accordance with examples as disclosed herein. The second set of manufacturing operations may support separating the vertical stack of layers into one or more linear layered stacks 805.

For example, the second set of manufacturing operations may include forming one or more cavities in the placeholder material 340-b. In some cases, the one or more cavities may be formed between trenches which are adjacent in the direction parallel along which the one or more trenches 305-a extend. For example, as illustrated in FIG. 8B, the trench 305-a-1 and the trench 305-a-2 extend a first horizontal direction (e.g., the x-direction) and are adjacent in the first horizontal direction. In such examples, material between the trench 305-a-1 and the trench 305-a-2 may be removed to form the one or more cavities. Removing the material to form the one or more cavities may physically separate each of the linear layered stacks 805 from other linear layered stacks 805 of the memory array 800-b. The second set of manufacturing operations may additionally include depositing the placeholder material 340-b within the one or more cavities to form one or more pillars 810, which may connect adjacent trenches 305-a, such as the trench 305-a-1 and the trench 305-a-2.

FIG. 8C illustrates an example of a memory array 800-c after a third set of manufacturing operations that support methods to increase cell density using a lateral etch in accordance with examples as disclosed herein. The third set of manufacturing operations may include operations that support forming one or more cavities 425-a in the vertical stack of layers. For example, the third set of manufacturing operations may include exhuming the placeholder material 340-b to form the one or more cavities 425-a. Each cavity 425-a may expose a sidewall of one or more pillars 405-a. In some examples, prior to forming the one or more cavities 425-a, the third set of manufacturing operations may include forming a cap 430-a on each of the pillars 405-a, which may protect the pillars 405-a during the exhuming process (e.g., may prevent or reduce the removal of materials of the pillars 405-a while exhuming the placeholder material 340-b).

FIG. 8D illustrates an example of a memory array 800-d after a fourth set of manufacturing operations that supports methods to increase cell density using a lateral etch in accordance with examples as disclosed herein. The fourth set of manufacturing operations may include operations that support forming one or more vertical stacks of word lines 815. For example, the fourth set of manufacturing operations may include removing the material 315-b from the vertical stack of materials, such as by using a material removal process selective to the material 315-a (e.g., a wet etch), to form one or more voids between layers of the material 320.

The fourth set of manufacturing operations may further include depositing a conductive material to fill the one or more voids, and removing a portion of the conductive material from the memory array 800-d, for example using an etching or etch-back operation, to form the one or more vertical stacks of word lines 815. In some cases, removing the portion of the conductive material may expose one or more sidewalls of the pillars 405-a. Additionally, removing the portion of the conductive material 435 may electrically isolate each vertical stack of word lines 815 from other vertical stacks of word lines 815. Each vertical stack of word lines 815 may extend in a first horizontal direction (e.g., the x-direction), and adjacent pairs of vertical stacks of word lines 815 in a second horizontal direction (e.g., the y-direction) may be separated by and in contact with opposing sidewalls of one or more pillars 405-a between the adjacent pair.

FIG. 8E illustrates an example of a memory array 800-e after a fifth set of manufacturing operations that supports methods to increase cell density using a lateral etch in accordance with examples as disclosed herein. The fifth set of manufacturing operations may include operations that support forming one or more memory cells 820 from each of the one or more pillars 405-a. For example, the fifth set of manufacturing operations may include removing the one or more caps 430-a and, in some cases, filling the one or more cavities 425-a with an insulating material 825 (e.g., a sealing material).

Because each vertical stack of word lines 815 may be independently driven (e.g., by a word line driver), each pillar 405-a may form multiple (e.g., two) stacks of memory cells 820 (e.g., multiple strings 220), each stack of memory cells 820 coupled with a separate vertical stack of word lines 815. For example, a pillar 405-a may include a stack of memory cells 820-a coupled with a vertical stack of word lines 815-a, and may include a stack of memory cells 820-b coupled with a vertical stack of word lines 815-b.

The memory array 800-e may undergo additional manufacturing operations to incorporate the one or more memory cells 820 into a memory device, such as a memory device using the memory architecture 200 as described with reference to FIG. 2. For example, a memory cell 820 may be an example of a memory cell 205, and may be an example of a transistor that includes a charge trapping structure.

FIG. 9A illustrates an example of a memory array 900-a after a set of manufacturing operations that supports methods to increase cell density using a lateral etch in accordance with examples as disclosed herein. The set of manufacturing operations may include operations that support forming one or more trenches 905 in a vertical stack of layers 910. For example, the set of manufacturing operations may include depositing alternating layers of a first material 915, such as a nitride material, and a second material 920, such as an oxide material or other dielectric or insulating material, to form the vertical stack of layers 910. In some cases, the first material 915, the second material 920, or both may be selective to a material removal process, such as a wet etch. For example, the first material 915 may be substantially removed using the wet etch, while the second material 920 may be substantially preserved by the wet etch (e.g., the wet etch may be selective to the first material 915).

In some cases, the vertical stack of layers 910 may be formed over a layered substrate 925. In such cases, the set of manufacturing operations may further support depositing or otherwise forming the layered substrate 925. The layered substrate 925 may include a layer of a semiconductor material 930 disposed between multiple (e.g., two) layers of a semiconductor material 935. The semiconductor material 930 may be deposited as an undoped semiconductor material, such as undoped polysilicon, and the semiconductor material 930 may be deposited as a doped semiconductor material, such as polysilicon doped with boron or other dopants, such that the semiconductor material 930 may be an example of a p-type semiconductor material (e.g., p-type polysilicon). In some examples, each layer of the semiconductor material 930 may include a layer of oxide material between the layer of the semiconductor material 930 and the semiconductor material 935.

The set of manufacturing operations may include etching (e.g., dry etching) the vertical stack of layers 910 and, in some cases, at least a portion of the layered substrate 925 to remove material from the vertical stack of layers 910, the layered substrate 925, or both to form the one or more trenches 905, which may be examples of cavities or voids within the vertical stack of layers 910. In some cases, the one or more trenches 905 may extend in the x-direction, as illustrated in FIG. 9A. Alternatively, the one or more trenches 905 may extend in the y-direction.

FIG. 9B illustrates an example of a memory array 900-b after a second set of manufacturing operations that supports methods to increase cell density using a lateral etch in accordance with examples as disclosed herein. The second set of manufacturing operations may include operations that support filling the one or more trenches 905 with a placeholder material 940. For example, the second set of manufacturing operations may include depositing the placeholder material 940 within the one or more trenches 905 to fill (e.g., fully fill, at least partially fill) the voids associated with the one or more trenches 905. In some examples, the placeholder material 940 may be a sacrificial material, such as a sacrificial polysilicon material, a nitride material, an aluminum oxide material, a doped semiconductor material, or a combination thereof.

FIG. 9C illustrates an example of a memory array 900-c after a third set of manufacturing operations that supports methods to increase cell density using a lateral etch in accordance with examples as disclosed herein. The third set of manufacturing operations may include operations that support forming one or more piers 945 in the one or more trenches 905, which may provide mechanical support for the memory array 900-c during subsequent manufacturing operations.

For example, the third set of manufacturing operations may include etching (e.g., dry etching, anisotropic deep etching) the placeholder material 940 to remove portions of the placeholder material 940 and thus form one or more cavities within each trench 905. In some examples, the one or more cavities may expose a portion of the layered substrate 925, such as the semiconductor material 930, the semiconductor material 935, or both.

The third set of manufacturing operations may further include depositing a second placeholder material within the one or more cavities to form the one or more piers 945. In some examples, the placeholder material 940 and the second placeholder material 950 may be different sacrificial materials, and may be selective to different material removal processes. For example, the second placeholder material 950 may be a doped semiconductor material (e.g., a doped polysilicon), which may be selective to a particular material removal process. In some examples, the second set of manufacturing operations may additionally include depositing a liner material 955 within the one or more cavities prior to depositing the second placeholder material 950. The liner material 955 may act as a seal or barrier between the second placeholder material 950 and the vertical stack of layers 910.

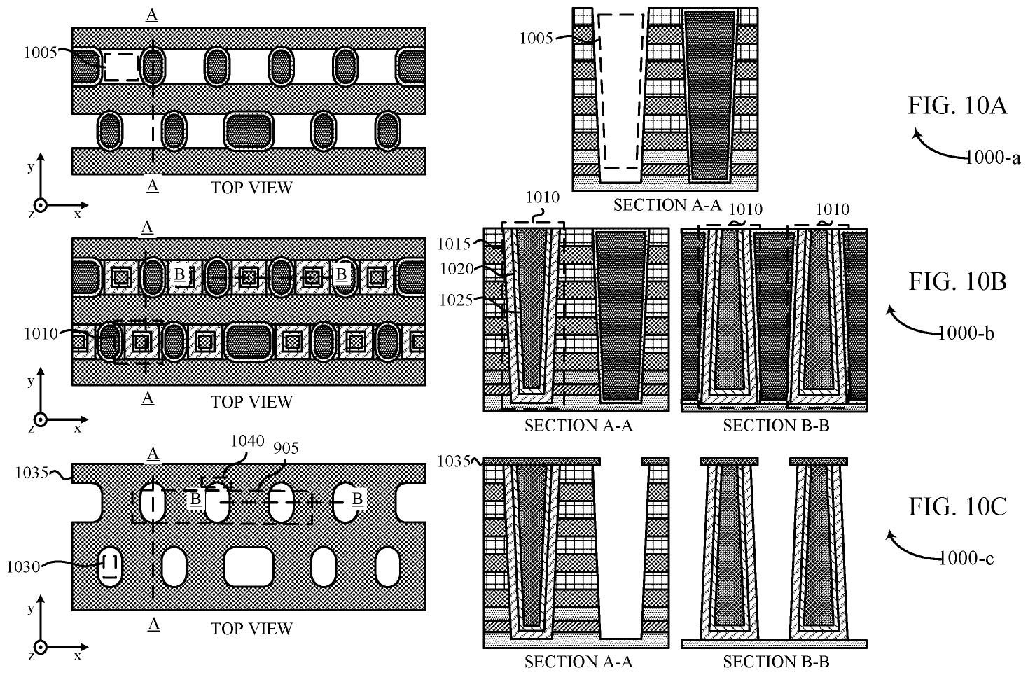

FIG. 10A illustrates an example of a memory array 1000-a after a fourth set of manufacturing operations that supports methods to increase cell density using a lateral etch in accordance with examples as disclosed herein. The fourth set of manufacturing operations may include operations that support forming one or more cavities 1005 in the vertical stack of layers 910. For example, the fourth set of manufacturing operations may include exhuming the remaining sacrificial material 940 (e.g., the sacrificial material 940 remaining after forming the piers 945) to form the one or more cavities 1005. Each cavity 1005 may expose a sidewall of one or more piers 945.

FIG. 10B illustrates an example of a memory array 1000-b after a fifth set of manufacturing operations that supports methods to increase cell density using a lateral etch in accordance with examples as disclosed herein. The fifth set of manufacturing operations may include operations that support forming one or more pillars 1010 in the one or more cavities 1005. For example, the fifth set of manufacturing operations may include depositing a material 1015 within each of the one or more cavities 1005 to contact exposed portions of the sidewalls of the piers 945, exposed portions or the layered substrate 925 (e.g., the semiconductor material 930, the semiconductor material 935), exposed portions of the vertical stack of layers 910, or a combination thereof. In some examples, the material 1015 may be an example of an insulating material, such as an oxide material. Additionally or alternatively, the material 1015 may be an example of a doped semiconductor material, such as a polysilicon or silicon glass material heavily doped with boron or phosphorous.

The fifth set of manufacturing operations may further include depositing a semiconductor material 1020 in the one or more cavities 1005 in contact with the material 1015. The semiconductor material 1020 may be an example of a polysilicon channel material, which may act as a channel for one or more transistors associated with each pillar 1010. For example, the semiconductor material 1020 may be an undoped or lightly doped polysilicon, such as a DHC material.

The fifth set of manufacturing operations may further include depositing an insulating material 1025 in the one or more cavities 1005 in contact with the semiconductor material 1020. The insulating material 1025 may be an example of an oxide or other dielectric material, and may provide mechanical support to a pillar 1010.

FIG. 10C illustrates an example of a memory array 1000-c after a sixth set of manufacturing operations that supports methods to increase cell density using a lateral etch in accordance with examples as disclosed herein. The sixth set of manufacturing operations may include operations that support forming one or more cavities 1030 within the one or more trenches 905. For example, the sixth set of manufacturing operations may include removing the one or more piers 945 (e.g., using a wet etch process selective to the second placeholder material 950), which may form the one or more cavities 1030. In some examples, removing the one or more piers 945 may include removing the liner material 955, for example by extending the etching beyond sidewalls of the one or more trenches 905, which may form one or more voids 1040. Additionally or alternatively, the material removal process to remove the second placeholder material 950 may preserve the liner material 955.

In some examples, prior to forming the one or more cavities 1030, the sixth set of manufacturing operations may include forming a mask 1035 over the memory array 1000-c, which may protect the pillars 1010 during the exhuming process (e.g., may prevent or reduce the removal of materials of the pillars 1010 while exhuming the second placeholder material 950).

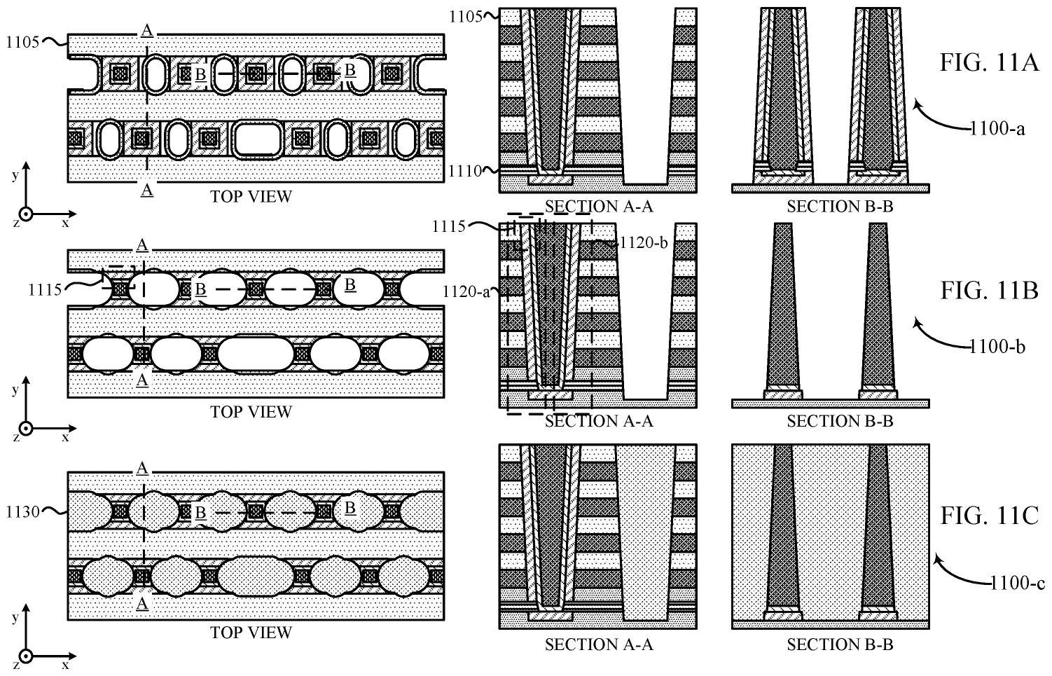

FIG. 11A illustrates an example of a memory array 1100-a after a seventh set of manufacturing operations that supports methods to increase cell density using a lateral etch in accordance with examples as disclosed herein. The seventh set of manufacturing operations may include operations that support forming one or more word lines 1105 within the vertical stack of layers 910. For example, the seventh set of manufacturing operations may include removing the material 915 from the vertical stack of layers 910, such as by using a material removal process selective to the material 915 (e.g., a wet etch), to form one or more voids between layers of the material 920. seventh sixth set of manufacturing operations may further include depositing a conductive material to fill the one or more void, and removing a portion of the conductive material from the vertical stack of layers 910, for example using an etching or etch-back operation. In some cases, removing the portion of the conductive material may expose one or more sidewalls of the pillars 1010. Additionally, removing the portion of the conductive material may electrically isolate each word line 1105 from other word lines 1105.

In some examples, the seventh set of manufacturing operations may further include doping the semiconductor material 935 to form a doped semiconductor material 1110. The doped semiconductor material 1110 may be an example of an n-type semiconductor, such as n-type polysilicon. In some cases, doping the semiconductor material 935 may include exposing the semiconductor material 935 to a dopant (e.g., in-sutu doping), depositing a doped silicon glass on the semiconductor material 935 (e.g., diffusion doping), exposing the semiconductor material 935 to high-energy ions (e.g., ion implantation), or a combination thereof.

FIG. 11B illustrates an example of a memory array 1100-b after an eighth set of manufacturing operations that support methods to increase cell density using a lateral etch in accordance with examples as disclosed herein. The eighth set of manufacturing operations may include operations that support forming one or more memory cells 1115 from each of the one or more pillars 1010. For example, the eighth set of manufacturing operations may include using a lateral etch (e.g., lateral wet etch) to remove a portion of the material 1015 and a portion of the semiconductor material 1020 from one or more sidewalls of each pillar 1010, which may expose the insulating material 1025 of each pillar 1010. Accordingly, each memory cell 1115 may be formed on a respective sidewall of the trench 905.

FIG. 11C illustrates an example of a memory array 1100-c after a ninth set of manufacturing operations that supports methods to increase cell density using a lateral etch in accordance with examples as disclosed herein. The ninth set of manufacturing operations may include operations that support forming an insulating material 1130. For example, the ninth set of manufacturing operations may include depositing the insulating material 1130 within each of the one or more cavities 1030, and within regions in which material was removed as part of the lateral wet etch to form the one or more memory cells 1115. In some examples, the insulating material 1130 may be a dielectric material, which may provide mechanical support to the memory array 1100-c. In some cases (e.g., if the one or more voids 1040 were formed, as described with reference to FIG. 10C), the insulating material 1130 may extend beyond the one or more trenches 905, which may reduce interference (e.g., reduce capacitance) between adjacent memory cells 1115 in the x-direction.

The memory array 1100-c may undergo additional manufacturing operations to incorporate the one or more memory cells 1115 into a memory device, such as a memory device using the memory architecture 200 as described with reference to FIG. 2. For example, a memory cell 1115 may be an example of a memory cell 205, and may be an example of a transistor that includes a charge trapping structure, such as the material 1015. Each memory cell 1115 or row of memory cells 1115 may be coupled with a respective word line 1105, which may an example of the word lines 265. Additionally, memory cells 1115 formed from a same side of a pillar 1010 (e.g., a vertical stack of memory cells 1115) may be coupled together as a string of memory cells 1120, which may be an example of a string 220.

In some cases, a string of memory cells 1120 may be coupled with a bit line 250, a source line 260, or both using one or more selecting transistors, such as TFTs, to support operation of the memory device. For example, the memory array 1100-c may include an array of switching components (e.g., TFTs, transistors) below the layered substrate 925, which may selectively couple the strings of memory cells 1120 (e.g., using a select line 235 to activate one or more switching components) with one or more bit lines. Accordingly, a memory cell 1115 in a given string of memory cells 1120 and at a given layer may be accessed by activating the switching component and, in some cases, the bit line, associated with the given string of memory cells 1120 and by activating the word line 1105 at the given layer.

In some examples, strings of memory cells 1120 formed from a same pillar 1010, such as the string of memory cells 1120-a and the string of memory cells 1120-b, may be selectively coupled with a same bit line using respective switching components to multiplex signals between the strings of memory cells 1120 and the bit line. Alternatively, the string of memory cells 1120-a and the string of memory cells 1120-b may each be selectively coupled with a separate bit line.

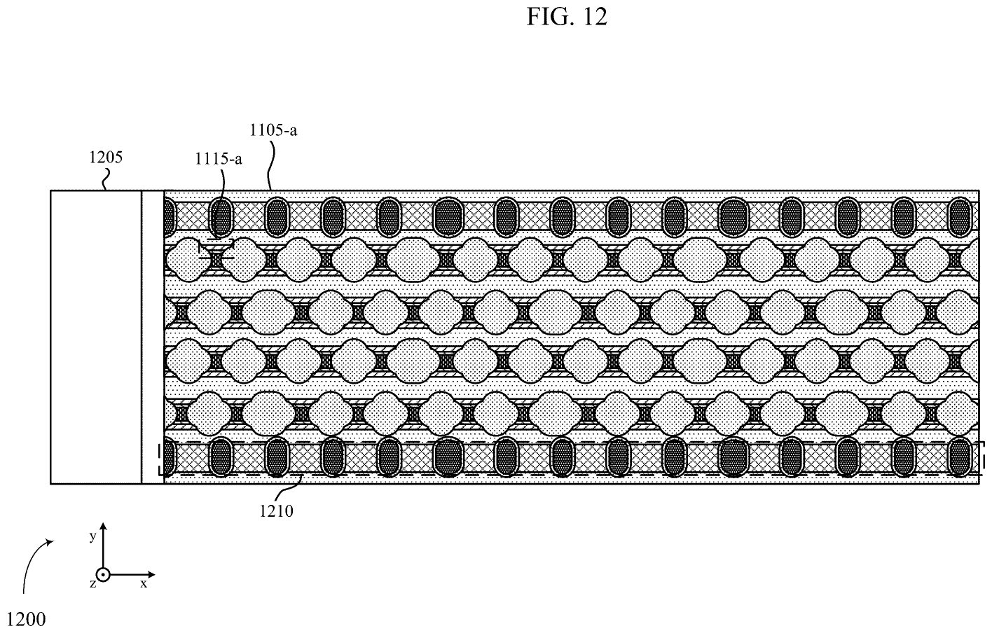

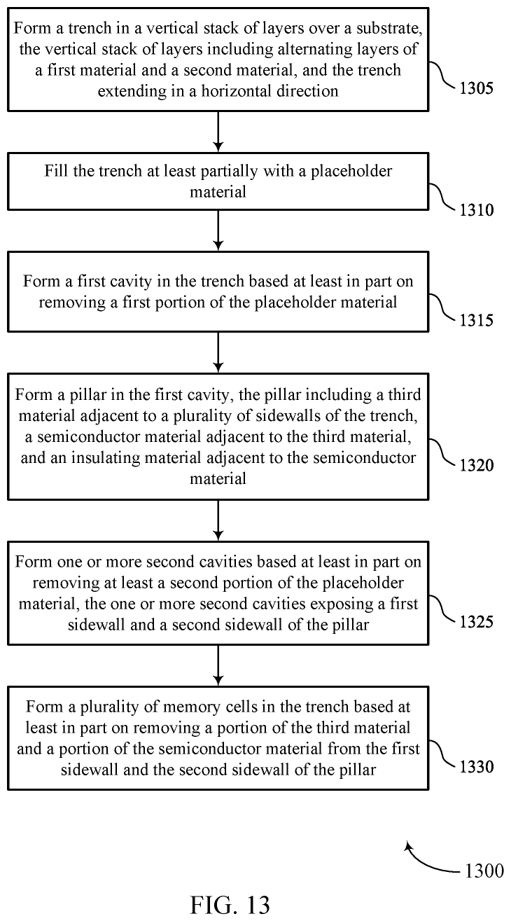

FIG. 12 illustrates an example of a memory array 1200 that supports methods to increase cell density using a lateral etch in accordance with examples as disclosed herein. The memory array 1200 may include aspects of a memory array manufactured using a set of manufacturing operations as described with reference to FIGS. 9A through 11C. For example, the memory array 1200 may include a layered stack of word lines 1105-a arranged along a vertical direction (e.g., along the z-direction), which may each be coupled with one or more memory cells 1115-a.

The memory array 1200 may support operations to access the memory cells 1115-a using a word line driver coupled with a word line staircase 1205. The word line staircase 1205 may include one or more contacts, which may each couple a respective subset of the one or more word lines 1105 with the word line driver.

In some examples, the memory cells 1115-a illustrated in FIG. 12 may be included in a block of memory cells 1115-a of the memory array 1200. In such examples, the memory array 1200 may include additional blocks of memory cells 1115-a, which may be separated from the block of memory cells 1115-a illustrated in FIG. 12 by a trench 1210, which may extend in the x-direction. The trench 1210 may be an example of a trench 905 as described with reference to FIG. 9A which may not have undergone manufacturing operations subsequent to the third set of manufacturing operations. That is, the trench 905 may include a placeholder material 940 and one or more piers 945, which may act as a slot or separator between adjacent blocks of memory cells 1115-a.

FIG. 13 illustrates a flowchart showing a method 1300 that supports methods to increase cell density using a lateral etch in accordance with examples as disclosed herein. The operations of method 1300 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 1305, the method may include forming a trench in a vertical stack of layers over a substrate, the vertical stack of layers including alternating layers of a first material and a second material, and the trench extending in a horizontal direction. The operations of 1305 may be performed in accordance with examples as disclosed herein.

At 1310, the method may include filling the trench at least partially with a placeholder material. The operations of 1310 may be performed in accordance with examples as disclosed herein.

At 1315, the method may include forming a first cavity in the trench based at least in part on removing a first portion of the placeholder material. The operations of 1315 may be performed in accordance with examples as disclosed herein.

At 1320, the method may include forming a pillar in the first cavity, the pillar including a third material adjacent to a plurality of sidewalls of the trench, a semiconductor material adjacent to the third material, and an insulating material adjacent to the semiconductor material. The operations of 1320 may be performed in accordance with examples as disclosed herein.

At 1325, the method may include forming one or more second cavities based at least in part on removing at least a second portion of the placeholder material, the one or more second cavities exposing a first sidewall and a second sidewall of the pillar. The operations of 1325 may be performed in accordance with examples as disclosed herein.

At 1330, the method may include forming a plurality of memory cells in the trench based at least in part on removing a portion of the third material and a portion of the semiconductor material from the first sidewall and the second sidewall of the pillar. The operations of 1330 may be performed in accordance with examples as disclosed herein.

In some examples, an apparatus (e.g., a manufacturing system) as described herein may perform a method or methods, such as the method 1300. The apparatus may include features, circuitry, logic, means, or instructions (e.g., a non-transitory computer-readable medium storing instructions executable by a processor), or any combination thereof for performing the following aspects of the present disclosure:

Aspect 1: A method or apparatus including operations, features, circuitry, logic, means, or instructions, or any combination thereof for forming a trench in a vertical stack of layers over a substrate, the vertical stack of layers including alternating layers of a first material and a second material, and the trench extending in a horizontal direction; filling the trench at least partially with a placeholder material; forming a first cavity in the trench based at least in part on removing a first portion of the placeholder material; forming a pillar in the first cavity, the pillar including a third material adjacent to a plurality of sidewalls of the trench, a semiconductor material adjacent to the third material, and an insulating material adjacent to the semiconductor material; forming one or more second cavities based at least in part on removing at least a second portion of the placeholder material, the one or more second cavities exposing a first sidewall and a second sidewall of the pillar; and forming a plurality of memory cells in the trench based at least in part on removing a portion of the third material and a portion of the semiconductor material from the first sidewall and the second sidewall of the pillar.

Aspect 2: The method or apparatus of aspect 1, further including operations, features, circuitry, logic, means, or instructions, or any combination thereof for removing the first material of the vertical stack of layers to form one or more voids after forming the one or more second cavities; depositing a conductive material to fill the one or more voids; and removing a portion of the conductive material to expose the first sidewall and the second sidewall of the pillar.

Aspect 3: The method or apparatus of aspect 2, where removing the portion of the conductive material forms one or more word line plates, each word line plate coupled with at least one respective memory cell of the plurality of memory cells.

Aspect 4: The method or apparatus of any of aspects 1 through 3, further including operations, features, circuitry, logic, means, or instructions, or any combination thereof for depositing the vertical stack of layers over the substrate, where forming the trench includes removing a portion of the vertical stack of layers.

Aspect 5: The method or apparatus of any of aspects 1 through 4, further including operations, features, circuitry, logic, means, or instructions, or any combination thereof for filling the first cavity with a second placeholder material; depositing a second vertical stack of layers over the vertical stack of layers based at least in part on filling the first cavity with the second placeholder material, the second vertical stack of layers including alternating layers of the first material and the second material; forming a second trench in the second vertical stack of layers, the second trench above the trench and extending in the horizontal direction; filling the second trench at least partially with the placeholder material; forming a third cavity in the second trench, the third cavity above the first cavity; and removing the second placeholder material from the first cavity, where forming the pillar further includes forming the pillar in the third cavity.

Aspect 6: The method or apparatus of any of aspects 1 through 5, where the plurality of memory cells includes a first memory cell on a first sidewall of the trench and second memory cell on second sidewall of the trench.

Aspect 7: The method or apparatus of aspect 6, further including operations, features, circuitry, logic, means, or instructions, or any combination thereof for removing the insulating material to form a gap between the first memory cell and the second memory cell.

Aspect 8: The method or apparatus of any of aspects 1 through 7, where the horizontal direction is parallel to a slot separating a first block including the plurality of memory cells from a second block including a plurality of second memory cells.

Aspect 9: The method or apparatus of any of aspects 1 through 8, where the horizontal direction is perpendicular to a slot separating a first block including the plurality of memory cells from a second block including a plurality of second memory cells.

Aspect 10: The method or apparatus of any of aspects 1 through 9, where the first material includes a nitride material, the second material includes a first oxide material, and the third material includes a second oxide material.

Aspect 11: The method or apparatus of any of aspects 1 through 10, where a second cavity of the one or more second cavities includes one or more rounded sidewalls.

FIG. 14 illustrates a flowchart showing a method 1400 that supports methods to increase cell density using a lateral etch in accordance with examples as disclosed herein. The operations of method 1400 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 1405, the method may include forming a trench in a vertical stack of layers over a substrate, the vertical stack of layers including alternating layers of a first material and a second material, the trench extending in a horizontal direction. The operations of 1405 may be performed in accordance with examples as disclosed herein.

At 1410, the method may include filling the trench at least partially with a placeholder material. The operations of 1410 may be performed in accordance with examples as disclosed herein.

At 1415, the method may include forming one or more piers in the trench based at least in part on removing at least a portion of the placeholder material. The operations of 1415 may be performed in accordance with examples as disclosed herein.

At 1420, the method may include removing the placeholder material to form a first cavity, the first cavity exposing sidewalls of each of the one or more piers. The operations of 1420 may be performed in accordance with examples as disclosed herein.

At 1425, the method may include forming a pillar in the first cavity, the pillar including a third material adjacent to a plurality of sidewalls of the trench, a semiconductor material adjacent to the third material, and an insulating material adjacent to the semiconductor material. The operations of 1425 may be performed in accordance with examples as disclosed herein.

At 1430, the method may include forming one or more second cavities based at least in part on removing at least a portion of the one or more piers, the one or more second cavities exposing a first sidewall and a second sidewall of the pillar. The operations of 1430 may be performed in accordance with examples as disclosed herein.

At 1435, the method may include forming a plurality of memory cells in the trench based at least in part on removing a portion of the third material and a portion of the semiconductor material from the first sidewall and the second sidewall of the pillar. The operations of 1435 may be performed in accordance with examples as disclosed herein.

In some examples, an apparatus (e.g., a manufacturing system) as described herein may perform a method or methods, such as the method 1400. The apparatus may include features, circuitry, logic, means, or instructions (e.g., a non-transitory computer-readable medium storing instructions executable by a processor), or any combination thereof for performing the following aspects of the present disclosure:

Aspect 12: A method or apparatus including operations, features, circuitry, logic, means, or instructions, or any combination thereof for forming a trench in a vertical stack of layers over a substrate, the vertical stack of layers including alternating layers of a first material and a second material, the trench extending in a horizontal direction; filling the trench at least partially with a placeholder material; forming one or more piers in the trench based at least in part on removing at least a portion of the placeholder material; removing the placeholder material to form a first cavity, the first cavity exposing sidewalls of each of the one or more piers; forming a pillar in the first cavity, the pillar including a third material adjacent to a plurality of sidewalls of the trench, a semiconductor material adjacent to the third material, and an insulating material adjacent to the semiconductor material; forming one or more second cavities based at least in part on removing at least a portion of the one or more piers, the one or more second cavities exposing a first sidewall and a second sidewall of the pillar; and forming a plurality of memory cells in the trench based at least in part on removing a portion of the third material and a portion of the semiconductor material from the first sidewall and the second sidewall of the pillar.

Aspect 13: The method or apparatus of aspect 12, further including operations, features, circuitry, logic, means, or instructions, or any combination thereof for forming a second trench in the vertical stack of layers, the second trench extending in the horizontal direction and separated from the trench in the horizontal direction by a portion of the vertical stack of layers; forming the placeholder material in the second trench; and forming one or more piers in the second trench based at least in part on removing a second portion of the placeholder material and removing the portion of the vertical stack of layers.

Aspect 14: The method or apparatus of any of aspects 12 through 13, further including operations, features, circuitry, logic, means, or instructions, or any combination thereof for removing the first material of the vertical stack of layers to form one or more voids after forming the one or more second cavities; depositing a conductive material to fill the one or more voids; and removing a portion of the conductive material to expose the first sidewall and the second sidewall of the pillar.

Aspect 15: The method or apparatus of aspect 14, where removing the portion of the conductive material forms one or more word lines, each word line coupled with a respective memory cell of the plurality of memory cells.

Aspect 16: The method or apparatus of any of aspects 12 through 15, where the plurality of memory cells includes a first memory cell on a first sidewall of the trench and second memory cell on second sidewall of the trench.

Aspect 17: The method or apparatus of any of aspects 12 through 16, further including operations, features, circuitry, logic, means, or instructions, or any combination thereof for forming a second insulating material in the trench, the second insulating material in contact with the plurality of memory cells.

It should be noted that the described methods include possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 18: An apparatus, including: a stack of first word lines distributed along a vertical direction and extending in a first horizontal direction, the stack of first word lines separated by a second material in the vertical direction; a stack of second word lines distributed along the vertical direction and extending in the first horizontal direction, the stack of second word lines separated from the stack of first word lines in a second horizontal direction; and a pillar between the stack of first word lines and the stack of second word lines, the pillar including a third material adjacent to a sidewall of the stack of first word lines and a sidewall of the stack of second word lines, a semiconductor material adjacent to the third material, and an insulating material adjacent to the semiconductor material.

Aspect 19: The apparatus of aspect 18, further including: a dielectric material between the stack of first word lines and the stack of second word lines, the dielectric material contacting a first sidewall and a second sidewall of the pillar.

Aspect 20: The apparatus of any of aspects 18 through 19, where the pillar includes a stack of first memory cells, each first memory cell coupled with a respective first word line of the stack of first word lines, and a stack of second memory cells, each second memory cell coupled with a respective second word line of the stack of second word lines.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The term “layer” or “level” used herein refers to a stratum or sheet of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials, or combinations thereof. In some examples, one layer or level may be composed of two or more sublayers or sublevels.

As used herein, the term “electrode” may refer to an electrical conductor, and in some examples, may be employed as an electrical contact to a memory cell or other component of a memory array. An electrode may include a trace, wire, conductive line, conductive layer, or the like that provides a conductive path between elements or components of a memory array.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processor, firmware, or any combination thereof. If implemented in software executed by a processor, the functions may be stored on or transmitted over, as one or more instructions or code, a computer-readable medium. Other examples and implementations are within the scope of the disclosure and appended claims. For example, due to the nature of software, described functions can be implemented using software executed by a processor, hardware, firmware, hardwiring, or combinations of any of these. Features implementing functions may also be physically located at various positions, including being distributed such that portions of functions are implemented at different physical locations.

For example, the various illustrative blocks and components described in connection with the disclosure herein may be implemented or performed with a general-purpose processor, a digital signal processor (DSP), an application-specific integrated circuit (ASIC), a field-programmable gate array (FPGA) or other programmable logic device, discrete gate or transistor logic, discrete hardware components, or any combination thereof designed to perform the functions described herein. A general-purpose processor may be a microprocessor, but in the alternative, the processor may be any processor, controller, microcontroller, or state machine. A processor may be implemented as a combination of computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

Computer-readable media includes both non-transitory computer storage media and communication media including any medium that facilitates transfer of a computer program from one place to another. A non-transitory storage medium may be any available medium that can be accessed by a general purpose or special purpose computer. By way of example, and not limitation, non-transitory computer-readable media can comprise RAM, ROM, electrically erasable programmable read-only memory (EEPROM), compact disk (CD) ROM or other optical disk storage, magnetic disk storage or other magnetic storage devices, or any other non-transitory medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, include CD, laser disc, optical disc, digital versatile disc (DVD), floppy disk, and Blu-ray disc, where disks usually reproduce data magnetically, while discs reproduce data optically with lasers. Combinations of the above are also included within the scope of computer-readable media.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A method, comprising:
forming a trench in a vertical stack of layers over a substrate, the vertical stack of layers comprising alternating layers of a first material and a second material, and the trench extending in a horizontal direction;
filling the trench at least partially with a placeholder material;
forming a first cavity in the trench based at least in part on removing a first portion of the placeholder material;
forming a pillar in the first cavity, the pillar comprising a third material adjacent to a plurality of sidewalls of the trench, a semiconductor material adjacent to the third material, and an insulating material adjacent to the semiconductor material;
forming one or more second cavities based at least in part on removing at least a second portion of the placeholder material, the one or more second cavities exposing a first sidewall and a second sidewall of the pillar; and
forming a plurality of memory cells in the trench based at least in part on removing a portion of the third material and a portion of the semiconductor material from the first sidewall and the second sidewall of the pillar.

2. The method of claim 1, further comprising:
removing the first material of the vertical stack of layers to form one or more voids after forming the one or more second cavities;
depositing a conductive material to fill the one or more voids; and
removing a portion of the conductive material to expose the first sidewall and the second sidewall of the pillar.

3. The method of claim 2, wherein removing the portion of the conductive material forms one or more word line plates, each word line plate coupled with at least one respective memory cell of the plurality of memory cells.

4. The method of claim 1, further comprising:
depositing the vertical stack of layers over the substrate, wherein forming the trench comprises removing a portion of the vertical stack of layers.

5. The method of claim 1, further comprising:
filling the first cavity with a second placeholder material;
depositing a second vertical stack of layers over the vertical stack of layers based at least in part on filling the first cavity with the second placeholder material, the second vertical stack of layers comprising alternating layers of the first material and the second material;
forming a second trench in the second vertical stack of layers, the second trench above the trench and extending in the horizontal direction;
filling the second trench at least partially with the placeholder material;
forming a third cavity in the second trench, the third cavity above the first cavity; and
removing the second placeholder material from the first cavity, wherein forming the pillar further comprises forming the pillar in the third cavity.

6. The method of claim 1, wherein the plurality of memory cells comprises a first memory cell on a first sidewall of the trench and second memory cell on second sidewall of the trench.

7. The method of claim 6, further comprising:
removing the insulating material to form a gap between the first memory cell and the second memory cell.

8. The method of claim 1, wherein the horizontal direction is parallel to a slot separating a first block comprising the plurality of memory cells from a second block comprising a plurality of second memory cells.

9. The method of claim 1, wherein the horizontal direction is perpendicular to a slot separating a first block comprising the plurality of memory cells from a second block comprising a plurality of second memory cells.

10. The method of claim 1, wherein the first material comprises a nitride material, the second material comprises a first oxide material, and the third material comprises a second oxide material.

11. The method of claim 1, wherein a second cavity of the one or more second cavities comprises one or more rounded sidewalls.

12. An apparatus, comprising:
a stack of first word lines distributed along a vertical direction and extending in a first horizontal direction, the stack of first word lines separated by a second material in the vertical direction;
a stack of second word lines distributed along the vertical direction and extending in the first horizontal direction, the stack of second word lines separated from the stack of first word lines in a second horizontal direction; and
a pillar between the stack of first word lines and the stack of second word lines, the pillar comprising a third material adjacent to a sidewall of the stack of first word lines and a sidewall of the stack of second word lines, a semiconductor material adjacent to the third material, and an insulating material adjacent to the semiconductor material.

13. The apparatus of claim 12, further comprising:
a dielectric material between the stack of first word lines and the stack of second word lines, the dielectric material contacting a first sidewall and a second sidewall of the pillar.

14. The apparatus of claim 12, wherein the pillar comprises a stack of first memory cells, each first memory cell coupled with a respective first word line of the stack of first word lines, and a stack of second memory cells, each second memory cell coupled with a respective second word line of the stack of second word lines.

15. A method, comprising:
forming a trench in a vertical stack of layers over a substrate, the vertical stack of layers comprising alternating layers of a first material and a second material, the trench extending in a horizontal direction;
filling the trench at least partially with a placeholder material;
forming one or more piers in the trench based at least in part on removing at least a portion of the placeholder material;
removing the placeholder material to form a first cavity, the first cavity exposing sidewalls of each of the one or more piers;
forming a pillar in the first cavity, the pillar comprising a third material adjacent to a plurality of sidewalls of the trench, a semiconductor material adjacent to the third material, and an insulating material adjacent to the semiconductor material;
forming one or more second cavities based at least in part on removing at least a portion of the one or more piers, the one or more second cavities exposing a first sidewall and a second sidewall of the pillar; and
forming a plurality of memory cells in the trench based at least in part on removing a portion of the third material and a portion of the semiconductor material from the first sidewall and the second sidewall of the pillar.

16. The method of claim 15, further comprising:
forming a second trench in the vertical stack of layers, the second trench extending in the horizontal direction and separated from the trench in the horizontal direction by a portion of the vertical stack of layers;
forming the placeholder material in the second trench; and
forming one or more piers in the second trench based at least in part on removing a second portion of the placeholder material and removing the portion of the vertical stack of layers.

17. The method of claim 15, further comprising:
removing the first material of the vertical stack of layers to form one or more voids after forming the one or more second cavities;
depositing a conductive material to fill the one or more voids; and
removing a portion of the conductive material to expose the first sidewall and the second sidewall of the pillar.

18. The method of claim 17, wherein removing the portion of the conductive material forms one or more word lines, each word line coupled with a respective memory cell of the plurality of memory cells.

19. The method of claim 15, wherein the plurality of memory cells comprises a first memory cell on a first sidewall of the trench and second memory cell on second sidewall of the trench.

20. The method of claim 15, further comprising:
forming a second insulating material in the trench, the second insulating material in contact with the plurality of memory cells.
